(19) United States
(12) Patent Application Publication
(10) Pub. No.: US 2003/0049372 A1
(43) Pub. Date: Mar. 13, 2003

(54) High rate deposition at low pressures in a small batch reactor

(76) Inventors: Robert C. Cook, Pleasanton, CA (US); Daniel L. Brors, Byron, CA (US); James Mitchener, Danville, CA (US); Gabe A. Ormonde, Lathrop, CA (US)

Correspondence Address: David H. Jaffer, Pillsbury Winthrop LLP, 2500 Hanover Street, Palo Alto, CA, 94304-1115, US

(21) Appl. No.: 10/216,079

(22) Filed: Aug. 9, 2002

Related U.S. Application Data
(63) Continuation-in-part of application No. 09/954,705, filed on Sep. 10, 2001.
Application No. 09/954,705 is a continuation-in-part of application No. 09/396,588, filed on Sep. 15, 1999, now Pat. No. 6,287,635.
Application No. 09/954,705 is a continuation-in-part of application No. 08/909,461, filed on Aug. 11, 1997, now Pat. No. 6,352,593.
Application No. 08/909,461 is a continuation-in-part of application No. 09/228,835, filed on Jan. 12, 1999, now Pat. No. 6,167,837.
Application No. 08/909,461 is a continuation-in-part of application No. 09/228,840, filed on Jan. 12, 1999, now Pat. No. 6,321,680.
Application No. 08/909,461 is a continuation-in-part of application No. 09/396,590, filed on Sep. 15, 1999, now Pat. No. 6,506,691.
(60) Provisional application No. 60/100,594, filed on Sep. 16, 1998.
(60) Provisional application No. 60/071,572, filed on Jan. 15, 1998.
(60) Provisional application No. 60/071,571, filed on Jan. 15, 1998.
(60) Provisional application No. 60/100,596, filed on Sep. 16, 1998.

(51) Int. Cl. C23C 16/00

(52) U.S. Cl. 427/248.1; 118/724; 118/715

(57) ABSTRACT

A chemical vapor deposition reactor including a wafer boat with a vertical stack of horizontally oriented susceptors serving as thermal plates and each having pins extending upward for suspending a wafer between a pair of susceptors. Reactant gas injector and exhaust apparatus are positioned to concentrate a forceful supply of reactant gas across each wafer at a speed in excess of 10 cm/sec. The pressure is held in the range of 0.1 to 5,000 mTorr. The forceful gas flow avoids gas depletion effects, thinning the boundary layer and resulting in faster delivery of reactants to substrate surfaces, resulting in surface rate reaction limited operation. A plurality of individually controllable heaters are spaced vertically around the sides of the boat. Temperature sensors monitor the temperature along the boat height and provide input to a controller for adjusting the heater drive to optimize the temperature uniformity.

This application is a continuation in part of (a) U.S. application Ser. No. 09/954,705 filed Sep. 10, 2001 which is a continuation in part of U.S. application Ser. No. 09/396,588 (U.S. Pat. No. 6,287,635) filed Sep. 15, 1999 (which claims the benefit of U.S. Provisional Application Serial No. 60/100,594 filed Sep. 16, 1998), which is a continuation in part of (i) U.S. application Ser. No. 08/909,461 (U.S. Pat. No. 6,352,593) filed Aug. 11, 1997, (ii) U.S. application Ser. No. 09/228,835 (U.S. Pat. No. 6,167,837) filed Jan. 12, 1999 (which claims the benefit of U.S. Application Serial No. 60/071,572 filed Jan. 15, 1998), and (iii) U.S. application Ser. No. 09/228,840 (U.S. Pat. No. 6,321,680) filed Jan. 12, 1999 (which claims the benefit of U.S. Provisional Application Serial No. 60/071,571 filed Jan. 15, 1998); and (b) U.S. application Ser. No. 09/396,590 filed Sep. 15, 1999 (which claims priority from U.S. Application Serial No. 60/100,596 filed Sep. 16, 1998). The disclosures of each of the foregoing applications are hereby incorporated by reference.

### 1. BACKGROUND OF THE INVENTION

1. Field of the Invention

The present invention relates to methods and apparatus for chemical vapor deposition (CVD) and atomic layer deposition (ALD) of various materials, and more particularly to a method employing a novel combination of gas flow, temperature and pressure to achieve high rates of deposition, and an improved apparatus for heating substrates in a reactor wherein a heater is provided with a plurality of separately adjustable temperature zones for improving substrate temperature uniformity in a small batch reactor.

2. Brief Description of the Prior Art

Although the following describes the deposition of silicon in various forms it is understood that a wide variety of other materials are deposited via CVD and ALD where the same considerations apply. Amorphous, polycrystalline and epitaxial silicon are used in the manufacturing of semiconductor devices and deposited onto substrates (i.e. wafers) by Chemical Vapor Deposition (CVD). Deposition is accomplished by placing substrates (or substrate) in a vacuum chamber, heating the substrates and introducing silane or a similar precursor such as disilane, dichlorosilane, silicon tetrachloride and the like, with or without other gases wherein the precursor disassociates at the hot surfaces resulting in silicon deposition. Numerous CVD reactors and associated processes have been successful in the deposition of silicon. Silicon films are required to have certain properties deemed useful in the manufacturing of semiconductor devices. The films must have high purity, and uniform thickness and composition across the substrate. Other properties have more recently become important as device sizes have become smaller. A high rate of deposition is now important to reduce the thermal budget, i.e. the amount of time the substrate is at temperature during processing. Higher deposition rates also translate to higher wafer throughputs and shorter cycle times. Very smooth film surfaces are necessary to print the sub-micron features required in today's integrated circuits. Smooth, fine grained films when patterned into features also result in features with smoother edges. In order to optimize the film properties, the temperature of the substrate needs to be held within a fraction of a degree during the CVD process. For example, in the case of polycrystalline silicon deposited at 620-660° C., a 10-degree difference in temperature results in a 20 percent change in the deposition rate. Thus, a one or two degree difference across a substrate can cause a two to five percent variation in the film thickness across the substrate. Ten years ago a five percent variation across a 150-mm substrate was considered satisfactory by the semiconductor industry. Today semiconductor manufactures are requiring a one percent or less variation in film thickness across a 300-mm substrate and from one substrate to another. In the case of polysilicon deposition, this translates to less than one half degree Celsius variation across a substrate and from substrate to substrate. Since the substrate is in a low pressure vacuum chamber, heating by convection is not feasible, nor is heating by conduction. Radiant heating has proven to be the most accepted method, with the heater/lamps outside the CVD chamber. In the prior art, a typical LPCVD (Low Pressure Chemical Vapor Deposition) system is depicted in FIG. 1 and consists of a chamber having a quartz tube 10 and chamber seal plate 11 into which is inserted a boat 12 carrying a plurality of substrates 13. Reactant gases 14 such as silane or other similar precursor and hydrogen and a dopant gas such as phosphine enter the seal plate 11 and flow to the vacuum exhaust port 15. A plurality of heater elements 16 are separately controlled and adjustable to compensate for the well-known depletion of the feed gas concentration as the gas flows 14 from the gas injection tube 17 to the chamber exhaust port 15. This type of deposition system typically operates in the 100 mTorr to 200 mTorr range and with typically 100 to 200 sccm silane flow diluted with hydrogen. Operating at this low partial pressure of silane, or other similar precursor, results in low deposition rates of typically 30 to 100 angstroms per minute. Operation at higher concentrations of the reactant gases results in non-uniform deposition across the substrates and great differences in the deposition rate from substrate to substrate due to gas depletion effects. Increased flow rates may improve the deposition uniformity at higher pressures, however increased pressures result in gas phase nucleation causing particles to be deposited on the substrates. A disadvantage of the reactor of FIG. 1 is that increasing reactant gas flow relative to a wafer surface in the reactor of FIG. 1 is problematical. A high gas velocity is not achievable due to the wafer surfaces lying perpendicular to the general flow of reactant gases. Also, the resistance to reactant gas flow is strongly dependent on the number of wafers in the reactor. This makes separate calibration necessary for different wafer load sizes. There are other problems associated with this reactor, such as film deposition on the interior quartz tube 10, which decreases the partial pressure of the reactive feed gas concentrations near the surface of the substrates 13 resulting in reduced deposition rates and potential contamination caused by the film deposited on the tube wall flaking off and depositing on the substrates 13. Finally, to offset the depletion of the reactive chemical species from the entrance to the exit of this style reactor, a temperature gradient is created across the substrate load zone such that the deposition rate from substrate to substrate is equal, however in the case of polycrystalline silicon deposition, this creates a different problem because the grain size is temperature dependent and the temperature gradient causes the polycrystalline silicon grain size to vary from substrate to substrate. This variation in grain size from substrate to substrate can cause problems with the subsequent patterning of the polycrystalline silicon, resulting in variations in the electrical performance of the integrated circuits in which the polycrystalline silicon is used.

Another prior art reactor is illustrated in FIG. 2. This is a vertical-flow reactor that reduces the gas flow depletion effect of the reactor depicted in FIG. 1. The substrates 18 are placed on a substrate carrier 19 which is placed in a vacuum chamber having a quartz bell jar 20 and a seal plate 21. The quartz bell jar 20 is surrounded by heater 22 to heat the substrates 18 to the required deposition temperature. Reactant gases such as silane and hydrogen are introduced through ports 33 and 24 and flow through the gas injection tube 25. The reactant gases 26 flow across the substrates 18 and are evacuated through port 27 by a vacuum pump (not shown) attached to port 27. This arrangement resulted in greatly reduced gas depletion effects compared with the reactor of FIG. 1, however silicon deposition occurs in the gas injection tube 25 and results in particles of silicon being deposited on the substrates 18. In addition, uniform temperature control over the substrates is very difficult to maintain, resulting in non-uniform silicon deposition over the substrates 18.

FIG. 3 shows a single wafer reactor which overcomes many of the short comings of the batch reactors shown in FIGS. 1 and 2, and is described in detail in U.S. Pat. No. 5,607,724. In FIG. 3, the substrate 28 is placed in a vacuum chamber 29 onto a rotatable pedestal 30. The substrate 28 is heated by lamps 31 and 32 through transparent walls 33 and 34 respectively. Reactant gases 35 enter the vacuum chamber 29 from port 36 and exit through port 37. Since the substrate 28 is rotated and heated on both surfaces from lamps 31 and 32, good temperature uniformity over the substrate 28 is obtained, resulting in good film uniformity over the substrate 28. A major problem associated with the reactor in FIG. 3 is the limited throughput (i.e. the number of substrates processed per hour) as compared to a batch reactor. This problem can be addressed by increasing the operating pressure to 10 Torr or greater, resulting in high deposition rates exceeding 1000 angstroms per minute, however operating the reactor at such high pressures can result in a gas phase reaction where silicon particles are formed in the gas and deposit on the substrate as particles. Also, deposition at high pressures changes the grain structure of the polysilicon. Another problem associated with the reactor is the tendency for silicon to be deposited on the quartz walls 33, 34 resulting in loss of radiant energy transmission from the lamps 31 causing non-uniform heating of the substrate and resulting in non-uniform film deposition on the substrate 28. Additionally the silicon deposited on quartz wall 33 can flake off and fall onto the surface of substrate 28.

In summary of the prior art, silicon films are required to have certain properties deemed useful in the manufacturing of semiconductor devices. The deposited silicon films must have high purity and uniform thickness and composition across the substrate. Recently other properties have become important as device sizes have become smaller. A high rate of deposition is now important to reduce the thermal budget, i.e. the time and temperature that the substrate is at elevated temperatures during processing. Very smooth uniform and reproducible film surfaces are also required to successfully print sub-micron features required in today's semiconductor integrated circuits. Because of this, there is a need to minimize temperature variations.

### SUMMARY

It is therefore an object of the present invention to provide a method and apparatus for CVD resulting in an increased rate of uniform deposition of materials on a substrate.

It is a further object of the present invention to provide a method and apparatus providing more rapid and uniform deposition of material on a substrate in a small batch reactor.

It is a still further object of the present invention to provide a method and apparatus that results in increased deposition rates and with surface roughness comparable to that obtained only at lower deposition rates in conventional furnace type batch reactors.

It is another object of the present invention to provide a method and apparatus for CVD in a small batch reactor that reduces the amount of time required at deposition temperatures, allowing the fabrication of smaller semiconductor devices.

It is an object of the present invention to provide an improved method and apparatus for minimizing temperature variations across a wafer and between wafers.

It is a further object of the present invention to provide multi-zone temperature control in a reactor.

It is another object of the present invention to provide a method and apparatus for the deposition of materials on a multiplicity of substrates via atomic layer deposition (ALD).

It is yet another object of the present invention to provide a method and apparatus for the deposition of differing materials on one or more substrates via a sequential combination of ALD and CVD processes in the same reactor.

Briefly, a preferred embodiment of the present invention includes a method and apparatus for depositing CVD materials on a plurality of substrates in a batch reactor. The reactor includes a wafer boat with a vertical stack of a plurality of separate and horizontally oriented susceptors, each serving as a thermal plate, and having pins extending upward for supporting a wafer between each pair of susceptors, for allowing a free flow of reactant gas both above and below each wafer. Reactant gas injector and exhaust apparatus are positioned to concentrate a forceful supply of reactant gas across each wafer at a speed in excess of 10 cm/sec. The pressure is held in the range of 100 to 2000 mTorr. The forceful gas flow avoids gas depletion effects, thins the boundary layer and results in faster delivery of reactants to substrate surfaces, resulting in surface rate reaction limited operation. Since the susceptors between which wafers are placed are larger than the diameter of the wafer, they offer several advantages: (i) The space between the susceptors is an isothermal environment resulting in exceptional wafer temperature uniformity (ii) the susceptors rapidly heat the wafers from room temperature to process temperature when a cold wafer is placed in between hot susceptors (iii) the susceptors form the thermal mass of the system and the inter-susceptor gap defines the flow conductance from the injector to the exhaust port, eliminating the need for dummy wafers that are essential in a conventional furnace and (iv) the flow and thermal boundary layers are fully established before the gas flow reaches the wafer edge resulting in a uniform supply of reactant to the wafer surface. As the reactant gas traverses the thermal boundary layer initiated at the susceptor edge, it gets preheated before it reaches the wafer edge. As an example, this preheating is necessary for the uniform deposition of high quality silicon nitride. A plurality of individually controllable heaters are spaced vertically around the sides of the boat. The boat is surrounded by alternating heating and temperature controlled zones. Each vertical array of heaters is separated from the next heater array by a zone in which the temperature is or can be controlled. The heating zones are used to heat the boat, while the temperature controlled zones that are at a controlled lower temperature (e.g. RT-200° C.), provide a heat loss mechanism that permits the boat temperature to be controlled to a given set-point value. The temperature controlled zones also host components such as the gas injector showerhead, an exhaust port, a temperature sensing port, a remote plasma injection port, and other devices that must be maintained at or below a certain temperature for proper operation. In this respect, the heating arrangement differs from a conventional furnace employing a quartz tube in which the entire inner surface of the quartz tube is hot, complicating the integration of such components/devices. Temperature sensors monitor the temperature along the boat height and provide input to a controller for adjusting the heater drive to optimize the temperature uniformity. The reactor provides polycrystalline silicon and amorphous silicon deposition rates that are several times higher than in prior art systems at low pressure with surface roughness one half to one third lower than previously reported for conventional furnace type batch reactors. The high rate of deposition of the silicon film is achieved by the forceful reactive gas flow across the substrates. The convective gas flow across the wafer surface transports reactants from the edge of the wafer to the center of the wafer avoiding gas depletion effects. The gas stream passing across the substrates has the effect of thinning the boundary layer resulting in a faster delivery of the desired reactant(s) to the substrate surface. Across the wafer gas flow provides an enhanced source of unreacted gas(es) with the highest concentration(s) of the desired reactant species at the surface of the substrate. This allows the process to operate in a kinetically limited or surface rate reaction limited regime over the temperature range of 550° C.-700° C. and a pressure range of 100 mTorr-2000 mTorr, unlike conventional batch type furnaces that only operate in the mass transport regime at higher temperatures and higher deposition pressures. The multi-zone heaters and controller coupled with rotation of the boat provide improved temperature uniformity across the wafer. This temperature uniformity combined with the surface reaction rate limited operation, results in a high deposition rate in combination with enhanced across-wafer uniformity of critical film properties such as thickness, refractive index, crystalline content, roughness, grain size and other parameters. Achieving uniform film properties across the wafer is important for high process yield. Typically, step coverage of films deposited in the surface rate reaction limited regime is also superior to those deposited in the mass transport limited regime.

The high rates of deposition enabled by this invention at relatively low overall chamber pressures (e.g., 600 angstroms/minute for polycrystalline silicon at 750 mTorr at a typical process temperature of 660° C.) moves the reaction into the regime where the deposition rate approaches or exceeds the surface crystallization rate, resulting in the growth of very small crystals and therefore very smooth polycrystalline silicon films with a surface roughness on the order of 3 to 5 nm for films up to 2500 angstroms thick. The high concentration of unreacted gas at the wafer surface due to across the wafer gas flow results in a high density of nucleation sites during the early stages of film deposition that contributes to a finer grain size and smoother films. The films remain smooth even as the deposition temperature is varied over the range of 620° C.-660° C.

Due to the rapid rate of deposition, the method reduces the time a substrate must be at deposition temperature from a conventional 2 or more hours for a conventional batch furnace to approximately 10 minutes for a deposition of 2500 angstroms of polycrystalline silicon. This also enhances the wafer throughput and reduces the cycle time to process a batch of wafers.

The general principles discussed with respect to polysilicon deposition extend to other LPCVD processes such as deposition of amorphous Silicon, polySiGe, doped poly, SiH₄/O₂ based oxides, TEOS/O₂ base oxides, SiH₂Cl₂/N₂O based oxides, SiH₄/NH₃ based nitrides, SiH₂Cl₂/NH₃ based nitrides, BTBAS/NH₃ based nitrides, and oxynitrides amongst others. For all these applications, the concept of across the wafer gas flow allows the attainment of uniform film properties across the wafer and provides a wide process space in terms of temperatures, pressures and flow rates while minimizing reactant composition.

The unique thermal configuration consisting of the stack of susceptors and the multiple heating banks permits the reactor to be idled at or close to the process temperature in between wafer processing. This minimizes temperature cycling of the reactor and its components. In addition, the reactor can be vacuum integrated, i.e. the gas injector port, and wafer loading door/port of the reactor can be vacuum sealed to the gas supply and wafer handler, thereby minimizing the ingress of gaseous contamination (e.g. moisture, oxygen, etc.), that if present results in film contamination. The good vacuum integrity and absence of temperature cycling of the reactor minimizes thermal stress induced flaking of films deposited on the heated surfaces, and as a result the intervals between cleaning is extended.

The incorporation of a remote plasma injector in one of the temperature controlled zones makes the reactor compatible with both thermal and remote plasma in-situ cleans. In-situ cleans generally reduces system down-time since the system would otherwise have to be wet-cleaned which is a laborious and tedious process.

An advantage of the method of the present invention is that it provides substantially enhanced uniformity of film properties across the wafer while minimizing the consumption of reactant gas.

A further advantage of the method of the present invention is that its use results in a deposition rate several times higher than prior art methods used to achieve films of comparable surface roughness.

A still further advantage of the method of the present invention is that the high deposition rate requires the substrate to be at a deposition temperature (typically 600° C.) for only about 10 minutes compared with a required 2 or more hours using prior art methods resulting in comparable film surface roughness.

Another advantage of the method of the present invention is that the reduced times required at deposition temperature allows production of smaller semiconductor junction depths and therefore an overall reduced semiconductor device size.

Another advantage of the method of the present invention is that the reduced deposition time provides a higher wafer throughput and a shorter cycle time for processing of a batch of wafers.

Another advantage of the present invention is that it combines the wide processing regime, process flexibility and short cycle times of a single wafer LPCVD reactor with the overall wafer throughput of a conventional furnace style batch reactor.

Another advantage of the present invention is the ability to achieve very uniform across wafer and wafer to wafer CVD films over a broad process window.

Another advantage of the present invention is that it supports the atomic layer mode of deposition and epitaxial deposition but at substantially higher throughput compared to a single wafer reactor.

Another advantage of the present invention is that it supports a flexible lot size eliminating the expense of dummy wafers.

Another advantage of the present invention is that it increases the intervals between cleans and supports in-situ chamber cleans to remove deposited films from the interior of the reactor.

Another advantage of the present invention is that it allows the processing of substrates having different sizes (diameter) without any hardware or process recipe changes.

### 4. IN THE DRAWING

FIG. 1 is a sectional view showing a prior art LPCVD reactor;

FIG. 2 is a sectional view showing a vertical-flow prior art LPCVD reactor;

FIG. 3 is a sectional view showing a single wafer prior art LPCVD reactor;

FIG. 4 is a flow chart illustrating the steps of a preferred embodiment of the present invention;

FIG. 5(a) is a sectional view showing a heating system of the high velocity LPCVD reactor;

FIG. 5(b) illustrates the inter susceptor spacing, substrate position, and susceptor to injector/exhaust spacing;

FIG. 5(c) illustrates an alternative apparatus for preheating reactant gases;

FIG. 5(d) illustrates the arrangement of a boat using susceptors as shown in FIG. 5(c);

FIG. 5(e) illustrates an alternative apparatus for preheating reactant gases;

FIG. 6(a) is a sectional view rotated 45 degrees with respect to FIG. 5(a) showing the high velocity gas flow of the LPCVD reactor;

FIG. 6(b) illustrates a multiplenum gas injector;

FIG. 7 is a gas injector for ejecting the gas in close proximity to the susceptors for concentrating the reactant gas;

FIG. 8(a) is a cross-sectional view of a multi-wafer reactor for illustrating use of thermal blocks on the top and bottom of a wafer boat;

FIG. 8(b) illustrates the use of curved, wrap-around, thermal plates;

FIG. 9 is a cross-sectional view of a multi-wafer reactor for illustrating use of heaters above and below a wafer stack;

FIG. 10 is a cross-sectional view of a reactor employing multiple zone heaters above and below a wafer;

FIG. 11 illustrates a multi-zone resistance heater with a radial variation of the heating elements;

FIG. 12 is a cross-sectional view of a reaction chamber with a multiple substrate boat and three separately controllable resistance heaters;

FIG. 13 is a top cross-sectional view of the reactor of FIG. 12;

FIG. 14 is a cross-sectional view of the reactor of FIG. 12 showing injector and exhaust apparatus;

FIG. 15 is a perspective view of the multi-zone heater arrangement shown in FIG. 12;

FIG. 16 is a perspective view showing multi-zone heaters integrated/embedded in the walls of a vacuum chamber;

FIG. 17 is a cross sectional view illustrating an arrangement of thermal side plates and upper and lower susceptor plates and substrate suspension pins according to the present invention;

FIG. 18 is a sectional view of a thermal plate with a stepped recess for suspending a substrate;

FIG. 19 is a cross sectional view showing first and second parallel thermal plates with two lengths of pins with captivation recesses, with the pins extending from the lower plate for suspending a substrate;

FIG. 20 illustrates a tapered pin for captivating a substrate;

FIG. 21 is a cross-section of a multi-wafer reactor for illustrating the method and apparatus for injecting inert gas above and below a wafer boat;

FIG. 22 is a graph of deposition rate versus temperature;

FIG. 23 is a bar chart of frequency versus grain size;

FIG. 24 is a plot of surface roughness versus deposition temperature;

FIG. 25 is a plot of deposition rate versus silane flow;

FIG. 26 is a wafer contour map;

FIG. 27 is a perspective view of a reactor having alternating heating zones and controlled temperature zones;

FIG. 28 is a cross sectional view showing more detail of the reactor of FIG. 27; and

FIG. 29 is a flow chart of in-situ cleaning.

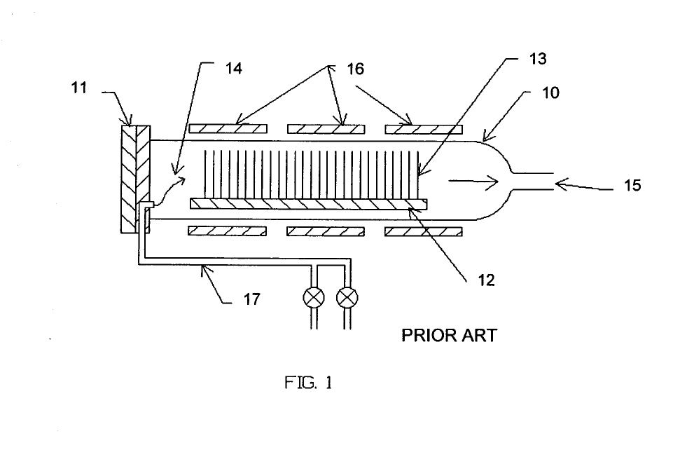

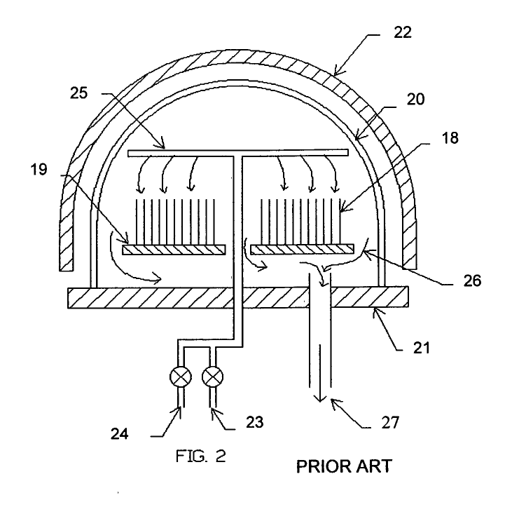

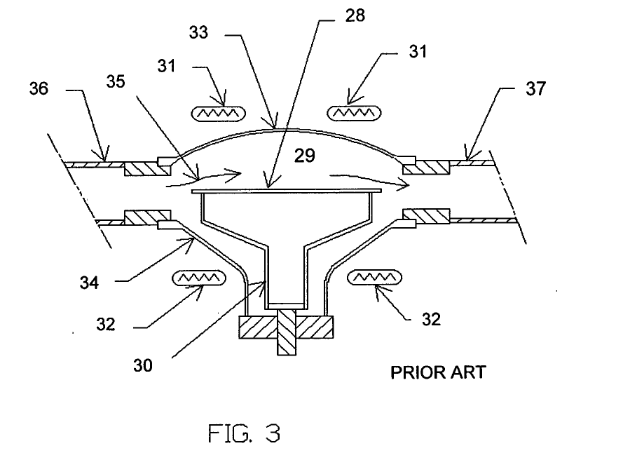

### 5. Detailed Description of the Preferred Embodiment

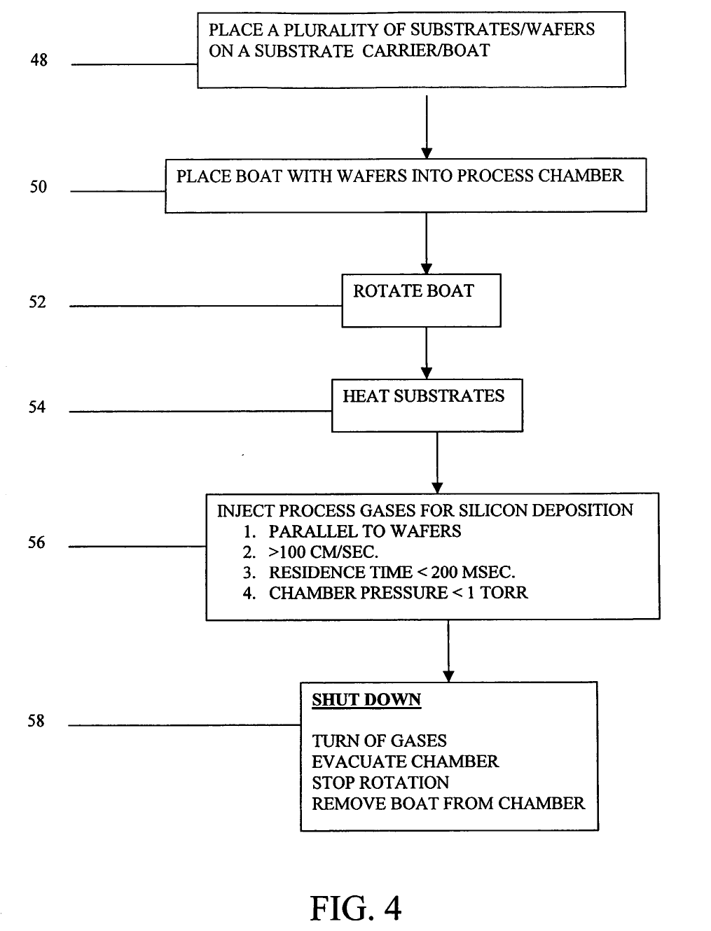

A preferred embodiment of the method of the present invention will now be described in reference to FIG. 4. The term silicon deposition or silicon used in this disclosure is used as a generic term to include polycrystalline silicon, amorphous silicon, and epitaxial silicon, with or without doping. Other materials deposited by CVD are also included in the present invention, such as silicon nitride, silicon oxides, tungsten, tungsten silicide, high-k dielectrics and other materials in which the deposition rate is enhanced by across the wafer gas flow.

In the particular case of the deposition of polycrystalline silicon, the process begins by placing a plurality of wafers on a multi-wafer carrier/boat 48. The boat with the wafers is placed in the process chamber 50 and rotated 52 and heated 54, with the wafers being heated as uniformly as possible. The preferred temperature range for silicon deposition is 500° C.-900° C. with a most preferred range of 600° C.-660° C. for polycrystalline silicon deposition. When the wafers are at the desired temperature, the flow of process reactant gas for silicon deposition is initiated 56. The preferred reactant gas is silane or a similar precursor such as disilane, dichlorosilane, silicon tetrachloride and the like, with or without other gases. Typically diluent gases such as N₂, Ar or H₂ are added to increase the convective gas velocity across the wafer. The gas pressure in the chamber is maintained at a selected pressure less than 3 Torr but preferably less than 1 Torr, and most preferably in the range from 100 to 2000 mTorr. The gas is introduced into the process chamber through a temperature controlled gas injector/showerhead in close proximity to the wafers wherein the gas is constricted to flow through a narrow vertical slot or a vertical series of small holes and directed in close proximity to each wafer edge to concentrate/force gas flow across each wafer surface. The gases are injected into the chamber with a velocity that is uniform across the face of the gas injector. Typical gas flows are chosen so as to achieve an across the wafer gas velocity of >10 cm/s and preferably >50 cm/s so that the gas residence time in the region above the wafer is under 500 ms and preferably under 200 ms. The gas residence time is the average duration the gases remain in the chamber before being evacuated. These gas velocities and gas residence times are achieved by adjusting the reactant and diluent gas flows and the size of the exhaust pipes and the pumping speed of the vacuum pump. The optimal gas velocities and residence times are process dependent. For some processes such as BTBAS/NH₃ based silicon nitride, the gas residence time must lie within an interval. Too low a residence time suppresses the deposition rate since the reactant leaves the chamber before it has had a chance to react. Too long a residence time degrades deposition uniformity and may result in gas phase nucleation. These limits for gas flows and residence times are best determined experimentally for the case of interest. The gas injector configuration of the present invention permits adjustment within a range of flow velocities and residence times to meet the specific requirement for optimum deposition of a selected material. The optimal flow rates are system dependent and are determined by monitoring deposition rate, deposition uniformity and film properties as a function of total flow while holding the other process and reactor parameters constant. The ranges of flow rates that give the optimal uniformity of thickness and film properties provide an indication of the upper and lower bounds for total flow rates. Also the film properties may change as the total flow rate is varied. For example, for conventional DCS/NH₃ silicon nitride deposited in a mini-batch reactor, good uniformity is obtained for total flows between 2 slm and 5 slm. However the lowest stress films are obtained at the higher flow rates (e.g. 4 slm). Thus the optimal flow rate for this case to achieve low stress, uniform films is 4 slm. For in-situ doped polysilicon, good thickness and dopant distribution uniformity were achieved at 5-8 slm total flow. The exact value of the flow rate is system dependent, and thus these numbers are only indicative of results obtained for a particular mini-batch reactor.

There may be regions of the chamber where the gas velocity is lower than desired and the residence time is too high. For example, this situation may occur at the top and bottom of the chamber that lie beyond the extremities of the gas injector and the exhaust port. While these regions may lie outside the active process space containing the substrates, and thus do not impact the film properties on the substrate, they may become regions of particle generation due to gas phase reactions. Inert purge gases may intentionally be introduced in these areas to reduce residence times and suppress gas phase reactions.

A preferred method of temperature control of the gas injector is by water cooling, i.e. passing the water through passages in the injector housing. Cooling of the injector prevents a gas phase reaction or deposition within the body of the injector. Thus, the pressure in the injector can be held higher than that of the reaction chamber so that the gas is dispersed uniformly through the holes up and down the length of the boat load. In some cases when the reactant gas has a low vapor pressure as in the case of reactants whose source is a liquid, the injector has to be moderately heated to avoid reactant condensation inside the body of the injector. In fact, for liquid sources, the temperature of chamber surfaces also has to be controlled to remain within specified limits to avoid unwanted condensation and deposition during processing. For many films such as silicon nitride and high-k dielectrics, the precursor source is a liquid. For both gaseous and liquid source CVD processes, subsequent to deposition, the gas is turned off and all remaining reactive gas(es) are evacuated from the chamber, the rotation is stopped, and the wafers removed 58. Multiple pump/purge cycles are generally performed after the reactant gases have been evacuated to bring the residual concentration of the reactants in the chamber to trace levels. This is important to prevent any further deposition on the wafer as the wafer is being unloaded and it also minimizes contamination of other chambers connected to the same wafer handler. Residual reactants can escape from the reactor chamber to the wafer transfer chamber and thence to other chambers during wafer transfer. The results achievable with the method of the present invention as described above in reference to FIG. 4 represent a major improvement in silicon deposition. This invention is not limited to the deposition of silicon and applies to the CVD of any material, wherein the deposition rate can be increased by forcing reactant gas flow over a substrate surface through use of a gas injector. As discussed in the section on prior art, previous batch CVD systems typically have deposition rates of 30 to 100 angstroms per minute, while this invention provides deposition rates of 600 angstroms per minute. Previous batch CVD systems typically deposit silicon with a surface roughness of 10-50 nm for films 2500 nm thick while this invention allows for silicon to be deposited with a surface roughness less than 5 nm and typically 3 nm for films 2500 nm thick. Film uniformity is typically <1% (max.−min./2×mean), measured between the center of a 200-mm diameter silicon wafer and a point 3-mm from the edge of the wafer. Although single substrate CVD systems have achieved high rates of silicon deposition (1,000-3,000 Å/minute), at such high deposition rates the growth structure is significantly altered. Generally in prior art systems, the poly-Si film morphology changes from a fine grained columnar microstructure at low deposition pressures to a random or equiaxed microstructure at higher pressures. In single wafer prior art reactors, higher pressures are used in combination with higher temperatures to enhance the deposition rate which compromises the columnar microstructure that is desirable for most poly-Si applications.

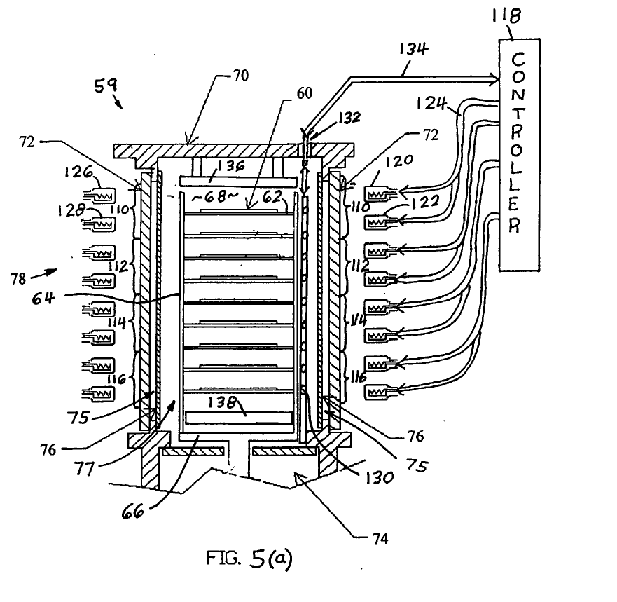

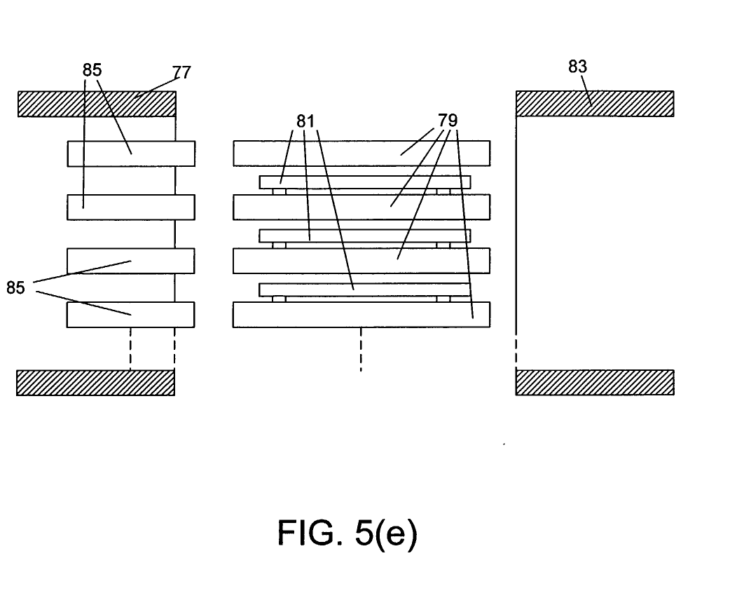

A description of a preferred apparatus as applied to the preferred embodiment will now be described in reference to FIGS. 5a-e, 6 and 7. FIG. 5(a) is a cross sectional view of a reactor 59 taken at an angle for description of the reactor heaters 78, windows 72 and thermal plates 76 relative to the carrier/boat 77. The deposition of silicon on a plurality of substrates 60 in accordance with the present invention will be described below. Substrates 60 are placed in the boat 77 on susceptors 62 which are supported by rods 64 which are attached to rotatable carrier 66, which is inserted into a vacuum chamber 68 which includes a top seal plate 70, quartz windows 72 and a lower vacuum load chamber 74 (not shown in detail). Substrates 60, susceptors 62, and rods 64 are heated to an appropriate temperature indirectly by thermal plates 76, which are heated by halogen lamps 78 through quartz windows 72. Carrier 66 is rotated at a speed of approximately 5-RPM. Alternative heating methods instead of lamps such as resistive heaters may be used. Each substrate 60 may rest directly on a susceptor 62, or it may be nested in a cavity within a susceptor 62, or it may be suspended between two susceptors 62, such as on three or more pins attached to the surface of a susceptor 62. The gas velocity across each substrate 60 depends on the position of the substrate 60 in the gap between the susceptors 62, as well as on the gap between the susceptors 62 and the thermal shield 76. In order to maximize the gas velocity across substrate 60, the gas must be directed at and concentrated/confined as much as possible to the gap. As shown more clearly in FIG. 5(b), the gap “G₁” between a substrate 60 and its corresponding upper susceptor 62 is preferably in the range of 0.2-1.5 inches. For ease of illustration in FIG. 5(b), item numbers 76 and 108 point to the same line, which illustrates either the edge of a thermal plate 76 or the edge of an injector or exhaust 108 port, depending on which one is being referred to. The gap G₂ between susceptors 62 and thermal shield plates 76 and/or injectors or exhausts 108 is preferably small relative to the gap G₃ between susceptors in order to confine/concentrate the gas in the gap. The minimum gap G₂ between a thermal shield 76 or injector/exhaust 108 and a susceptor is preferably in the range of 0.05-1.0 inches. Minimizing the distance between the thermal plates 76 and susceptors 62 improves heat transfer to the susceptors. The gap G₂ between a susceptor and a thermal shield may be decreased by using thermal shields that are semicircular and wrap around the susceptors. This is simply illustrated in FIG. 8(b) taken as a cross section A-A of a reactor 61. The view reference A-A is illustrated as indicated for example by the A-A section notation in FIG. 8(a). The reactor 61 of FIG. 8(b) is symbolically illustrated with many obvious details of construction being omitted that will be apparent to those skilled in the art, but differs from the reactor of FIG. 8(a) in that the heat shields 76 of FIG. 8(a) are flat, whereas the plurality of heat shields 63 of FIG. 8(b) are curved/semicircular. The reactor 61 includes a wafer boat (not shown) for processing a plurality of wafers, similar to the reactor of FIG. 8(a). FIG. 8(b) shows a reactant gas injector 65, and exhaust 67, a susceptor 69, a wafer 71, windows 73, and heater 75. Using semicircular thermal shields 63 that are in close proximity to susceptors 69 also reduces the temperature differential between shields 63 and susceptors 69. This reduces the power required to achieve a specified wafer temperature and also speeds up the ramp from a lower temperature when the wafers are loaded, to a higher processing temperature.

The various gaps G₁, G₂, G₃, G₄ (refer to FIG. 5(b)), may be varied along the length of the boat of the reactor 61, as well as the other reactors of the present invention to fine tune the uniformity of film properties between substrates in the batch. Typically the inter-susceptor gap G₃ varies between 0.5 and 1.5 inches. The substrate 60 is preferably positioned to provide a gap G₄ between the substrate 60 and lower susceptor 62 in the range of 0.05 to 0.25 inches. The thermal plate to susceptor gap G₂ typically varies between 0.1 and 0.5 inches. The optimal values are dependent on the specific reactor geometry and the desired processing results on the substrate. A preferred distance G₂ from the injector plate 76 to the susceptors 62 is in the range of 0.1 to 0.8 inches, and/or less than the distance G₃ between susceptors 62. The preferred and critical dimensions in order to achieve the degree of improved reactor performance achieved by the reactor of the present invention can also be described in relative dimensions. It is preferred that the thermal plate is positioned from each susceptor a distance G₂ that is less than the spacing G₃ between susceptors. The ratio G₂/G₃ of the distance G₂ to the spacing G₃ between the susceptors is preferably in the range of 0.2 to 1.0. The same preferred ratio of 0.2 to 1.0 applies to the ratio of the distance G₂ from the edge of the exhaust port, to the susceptor spacing

FIG. 5(b) and FIG. 8(b) also serve to illustrate another novel aspect of the present invention. Referring to FIG. 5(b), the wafer 60 diameter d₁ is notably shown to be less than the diameter d₂ of the susceptor 62. This is also shown in FIG. 8(b). This arrangement is preferred for the purpose of heating reactant gas by passing it over a portion of the susceptor unoccupied by the wafer i.e. a thermal boundary layer prior to passing over the wafer. As the reactant gas traverses the thermal boundary layer initiated at the susceptor edge, it gets preheated before it reaches the wafer edge. This preheating is necessary for improved uniform deposition of high quality silicon nitride. The distance d₃ can be termed the entry length for flow and thermal boundary layer equilibration. The entry length for the gas to arrive at a condition of laminar i.e. non-turbulent flow parallel to the susceptor surfaces, is typically three times the width G₃ of the channel (space between the susceptors). Ideally the distance d₃ should be two times to five times larger than the inter-susceptor spacing G₃ for typical flow rates and operating pressures encountered during LPCVD.

FIG. 5(c) shows an alternate susceptor embodiment 41 wherein the center portion 43 of the susceptors is removed. The open or donut shaped susceptor configuration reduces the resistance to gas flow, and therefore has the effect of increasing the amount of gas that passes over the substrates' surface for a given gas supply pressure, resulting in a corresponding increase in the deposition rate. Referring to FIG. 5(b), showing the standard solid type susceptors previously described, the gas flow across the top side of the substrate 60 is limited by the relative conduction associated with the space between the substrate 60 and the susceptor 62 above and is determined by the gap G₁. Referring to FIG. 5(d), a boat using open donut shaped susceptors 41 having the same inter susceptor gap, G₃ as in FIG. 5(b), will result in increased flow due to the increased space G₅ above the wafers 60, in much the same way that a pipe of larger inside diameter will have more volumetric flow than a pipe of smaller inside diameter for a given pressure. Thus, by using open, donut shaped susceptors, the productivity of the reactor can be increased in two ways. First, for a given boat size, the deposition rate is increased using the same number of susceptors with the same inter susceptor gap G₃. Secondly, by holding the deposition rate the same, the inter susceptor gap G₃ can be reduced, allowing a boat design with an increase in the number of susceptors in the load zone which means that more substrates can be processed in the same amount of time. However, a dummy wafer 45 will have to be used above the upper most wafer, shown at location 47, and also a dummy wafer needs to be used for each wafer position not occupied by a real wafer in order to maintain the same geometry and reactant gas flow for each wafer being processed. The use of dummy substrates is not required for solid susceptors when the process is strictly temperature dependent, nor in the case where the process is dominated by gas flow and the WiW, WtW and RtR uniformity and reproducibility tolerances permit. WiW is the film thickness non-uniformity within a wafer. WtW is the variation in mean film thickness from wafer to wafer in a batch, and RtR is the variation of the film thickness averaged over all the wafers in a batch from one run to the next.

Alternative methods of pre-heating the reactant gases can also be used. The above described method and apparatus wherein the reactant gases are preheated by a length of heated susceptor immediately prior to flowing across the substrate is preferred. A benefit of the preferred method and apparatus is that it minimizes the heated reactant's contact with and deposition on surfaces. FIG. 5(e) illustrates an alternative apparatus for preheating reactant gases. An injector manifold 77 is shown in close proximity to a boat with a vertical stack of susceptors 79. Substrates 81 are shown suspended between each pair of susceptors 79. An exhaust manifold 83 is also in close proximity to the susceptors for pulling/extracting the reactant gas. The pre-heating of reactant gases is accomplished by placing heated plates 85 in the injector manifold 77. The plates 85 can be positioned as close as is practical dimensionally to the susceptors 79 to minimize the amount of pre-heated gas escaping into other areas of the chamber. Various methods of heating the plates 85 will be apparent to those skilled in the art. A preferred method is to incorporate electrical heating elements within the plates 85. A simpler option is to heat the plates passively by allowing the susceptor boat and the thermal plates/shields to heat the plates radiatively. Other methods and apparatus for preheating the reactant gas will be apparent to those skilled in the art and these in combination with novel elements of the present invention are also included in the present invention.

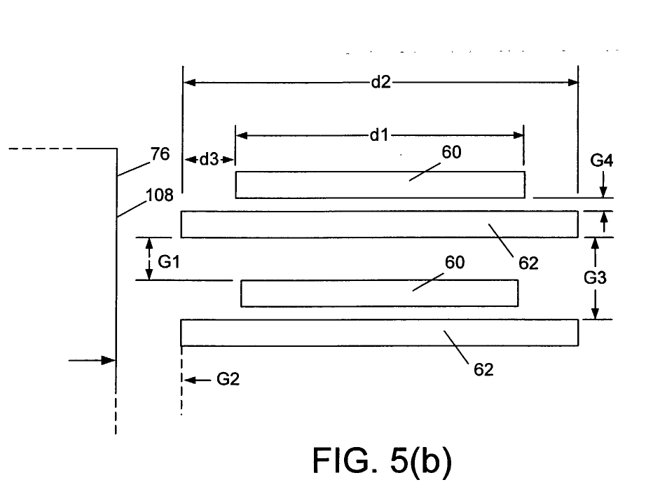

FIG. 6(a) is a cross sectional view of the reactor of FIG. 5(a) taken at an angle to show the details of reactant gas injection and exhaust apparatus that is positioned between the windows shown in FIG. 5(a). A single inlet plenum 91 is shown. Reactant gases 80 are injected into the plenum chamber 82 through tubes 84 and 86 through plenum wall 88. The reactant gases 80 are uniformly injected into the reaction chamber 68 through a series of holes 90, typically 0.020 inches in diameter with 100 to 200 such holes traversing the length of the gas injection plate 92, or a narrow slit, typically 0.005 inches wide traversing the length of the gas injection plate 92. FIG. 6(b) illustrates a multi-plenum injector that may be used instead of the single plenum injector 91 so that reactant gases are not pre-mixed upstream of the injection plate 92, but instead mix after injection into the chamber 68 on the low pressure side 93 of the gas injection plate 92. For example, a three plenum injector (not shown) can be used for LPCVD SiN using dicholorosilane and ammonia. The dicholorosilane and ammonia can be injected through two of the three plenums by injecting them through two tubes that open into separate cavities. Dicholorosilane and ammonia tend to react if mixed at high pressure and keeping them separate until they are injected into the chamber avoids particulate generating gas phase reactions. The third plenum can be used for injecting a cleaning gas such as CIF₃ or NF₃ that has been cracked to atomic fluorine by a remote plasma source. For ease of illustration, only two plenums 95 and 99 are shown in FIG. 6(b), separated by a wall 103. Inlet tubes 105 and 107 are used to supply assigned gas to the plenums 95 and 99, respectively. Each plenum has its own separate set of injection ports i.e. holes or slots, 111 and 113 for plenums 95 and 99, respectively. Referring again to FIG. 6(a), the reactant gases 80 flow across susceptors 62 and wafers 60 wherein the reactant gases 80 disassociate and deposit silicon, or other substance according to the reactant selected, on the susceptors 62 and wafers 60. Referring to FIG. 5(a), an inert gas, such as argon, is injected into the space 75 between the thermal plates 76 and quartz windows 72 to prevent the reactant gases 80 from entering the space between thermal plates 76 and quartz windows 72. The space between the quartz window 72 and thermal shields 76 is continuously purged with an inert gas to prevent ingress of reactant gases into this space. The purge gas is exhausted directly into the foreline of the vacuum pump or into the process chamber. The former is preferred to avoid unnecessary dilution of reactant gas in the process chamber. Thermal shields 76 serve three purposes. First, they prevent unwanted deposition on the quartz windows, although this is not a concern for certain applications such as oxidation or surface treatment. Second, they absorb heat from the individual tungsten halogen or infrared heating sources and re-radiate it to the susceptors for more uniform heating of the boat. Third, they can be used to reduce the flow of reactant gases around the boat. However for certain applications such as oxidation, annealing and surface treatment, the thermal shields may be absent and the boat can be heated directly by the lamps. If resistive heaters are used instead of lamps, they may be installed so that they serve as the vacuum seal to the chamber which then eliminates the need for the quartz windows, the thermal shields and the shield purge. Resistive heaters can also be used as a direct replacement for the lamps. Details of a resistive heater and temperature control will be given in the following text in reference to the figures of the drawing.

The reactant gases uniformly flow out of the vacuum chamber 68 through an exhaust plenum 115 to exhaust port 96. An exhaust baffle in the form of a plate 97 with rectangular slits or orifices 117 may be placed over the entrance to the exhaust plenum 115, for example at the position indicated, similar to the gas injection plate 92, to achieve a uniform exhaust of process gases along the height of the chamber. The size, number and distribution of the slits or orifices are selected to achieve the specified exhaust gas pattern while still achieving sufficient conductance. Additional gases may be introduced downstream of the exhaust baffle 97 to achieve dilution or abatement of the process gases. The introduction of an additional gas into the plenum interior 119 which is downstream from the baffle 97, is illustrated by a tube 121. The additional gas is added to the exhaust plenum for the purpose of abating or converting reaction by-products that would otherwise condense on surfaces, such as a throttle valve that controls chamber pressure, symbolically indicated by item 123 in FIG. 6(a). The exhaust baffle 97 also prevents back-flow of the added gas into the process chamber.

The process gas flow between one pair of susceptors is very similar to the flow between any other pair. The reason for this is that the gas injector introduces gas at a uniform velocity and the gap between each pair of susceptors 60 is the same. In addition, the gas is exhausted uniformly. The similarity of process gas flow over each substrate 60 leads to film properties that are similar on each substrate 60.

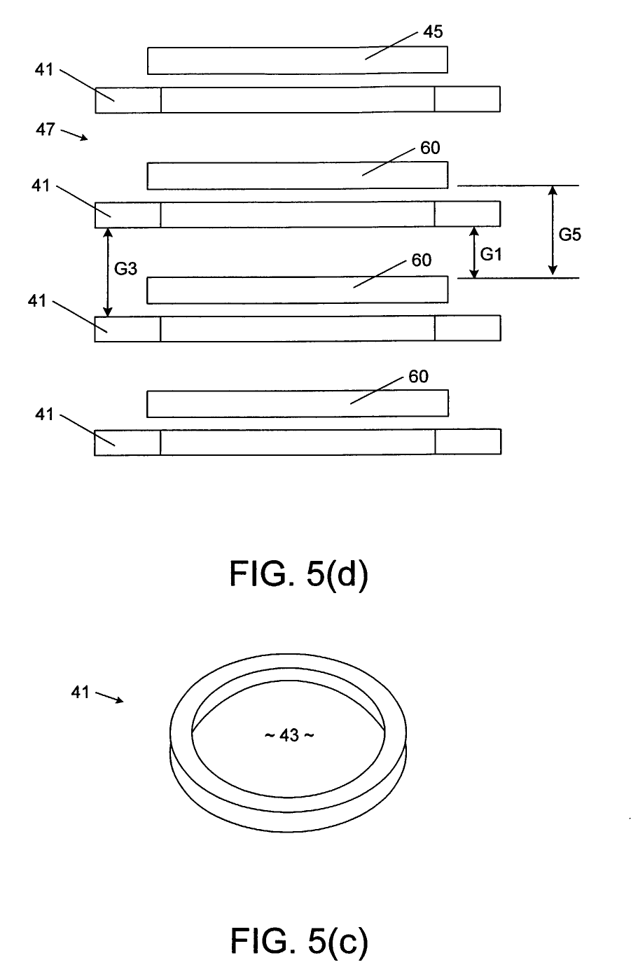

FIG. 7 shows a gas injector assembly 101 that can be used with a chamber similar to the one of FIG. 5(a). The assembly 101 would take the place of the injector apparatus of FIG. 6(a) including wall 88, inlets 84, 86 and injector plate 92. The injector assembly 101 accepts reactant gases through tubes 98 and 100 through plate 102 which is water cooled by passing water through channels (not shown) in plate 102 connected to water lines 104. In reference, for example to FIG. 6(a), the gases 80 are injected into the chamber 68 at high velocity through a series of small holes 106 (FIG. 7) or a narrow slit (not shown) in a plate 108. The diameter and number of holes 106 in plate 108 or the slit dimensions are selected so that the pressure upstream of plate 108 is substantially greater than the pressure in the chamber. This pressure differential injects gases 80 uniformly and at high velocity into the chamber. The holes may be flared on the outlet end to reduce gas jetting effects. The distribution and size of the holes may be varied across the face of the injector if a specific injection pattern of gases is desired. The plate 108 corresponds to plate 92 of FIG. 6. It should be noted here that the length “L” of the injector chamber 109 is preferably designed to place the face of plate 108 in close proximity to the susceptors 62 as discussed in reference to FIG. 5(b) and corresponding text so as to inject the gases in a concentrated form across the susceptors 62 and wafers 60 and minimize reactant gas pressure and flow elsewhere in the chamber 68. The process gases exit gas injector assembly 101 at a temperature corresponding to plate 108. The surface temperature of top plate 108 may be adjusted by its position relative to the edge of the susceptor boat. As mentioned before, injector chamber 109 can contain multiple plenums instead of a single plenum. For a 3 plenum injector, at least three tubes feed the injector, with each tube feeding one of the plenums. Each plenum has a corresponding set of holes 106, such as the holes/slots 111 and 113 of FIG. 6(b). The diameter, distribution and number of holes or slots may be different for each of the plenums.

For semiconductor applications, process cleanliness is crucial. The need to avoid gas phase nucleation, which is a source of particles, was discussed earlier in the present disclosure. In addition, it is vital that deposits on hot surfaces such as susceptors 62 and thermal shields 76 are not powdery and do not delaminate. By maintaining all hot surfaces within a certain temperature range which depends on the process chemistry, powdery deposits can be avoided. For polysilicon all heated surfaces should be in the temperature range from 500° C. to 900° C. Film delamination can be minimized by proper choice of materials for fabricating thermal shields 76 and susceptors 62, avoiding sharp corners in fabricated parts, minimizing temperature cycling of the parts, and surface treating the parts prior to the deposition and periodically during the deposition. For example, to minimize delamination of silicon nitride films, polysilicon deposition can be performed periodically to bind the silicon nitride to keep it from delaminating. For a variety of CVD applications, silicon carbide coated graphite or polysilicon can be used for the heated parts since they offer a good combination of mechanical strength, thermal stability, thermal conductivity, purity, and adhesion of deposited films. Despite these precautions, the deposited films will eventually delaminate when the total stress in the deposited films exceeds their adhesive strength or their mechanical strength. Thus the deposited films must be removed periodically.

One method of cleaning is done by removing thermal shields 76 and susceptors 62 and cleaning them in an appropriate chemical bath. A preferred method is to clean the parts in-situ with an in-situ thermal clean or an in-situ remote plasma clean. For either the thermal clean or the remote plasma clean, the cleaning gas must be injected into the process chamber. These gases are injected into the chamber using an injector that is analogous to the gas injector assembly described above for the process reactant gases. For thermal cleans, various gases such as ClF₃, NF₃ and HCl may be used. For remote plasma cleans atomic fluorine, generated by flowing NF₃ or CF₄ like gases through a remote plasma source, is injected into the chamber. The temperature of the thermal shield 76 and susceptors 62 is selected to maximize the removal of the deposited films without generating particles or etching the material of the shields and the susceptors. The internal chamber temperature is also controlled to prevent the formation of metallic fluorides that can volatilize during wafer processing, resulting in metal contamination in the wafer. With a proper choice of chamber components and surface temperatures, low metal contamination can be achieved following the in-situ clean. The in-situ clean is usually followed by pre-coating the chamber with 0.5-2 μm of poly-Si that passivates all cleaned surfaces, restores the deposition rate to a stable value, and getters any residual gaseous or metallic contamination that may be present. Depending on the application, the same remote plasma source may also be used for wafer surface conditioning either prior to the deposition, during the deposition, or following the deposition. The novel aspect of remote plasma cleaning according to the present invention is the injection of atomic fluorine through the vertical injector “showerhead” to obtain uniform cleaning rates up and down the stack of susceptors while evenly cleaning across the diameter of all the individual susceptors. In order to achieve uniform cleaning, a multi-step cleaning process may be employed. First the susceptor boat may be retracted from the chamber and the thermal shields can be cleaned. Next the susceptor boat can be lowered into the chamber and the susceptor boat can be cleaned. In order to achieve uniform etching along the diameter of the susceptor, the pressure and gas flow rates must be selected properly. For remote plasma cleans using NF₃ as the source gas, the optimal pressure for uniform etching of the boat was found to be 2-6 Torr. The total flow rate which is the sum of the carrier flow rate and the NF₃ flow rate controls the residence time of the atomic fluorine in between the susceptors. At very low total flow rates, the fluorine is consumed at the edge of the susceptor before it reaches the center of the susceptor, resulting in an etch rate that is high at the edge of the susceptor with minimal etching at the center of the susceptor. As the total flow is increased, more of the atomic fluorine is transported to the center of the susceptor, and the etch uniformity is improved. At very high flow rates, the residence time of the atomic fluorine at the edge of the susceptor is too low for appreciable etching, and the etching once again becomes non-uniform. The best etching uniformity for uniform cleaning with minimal over-etch is obtained at an optimal total flow that is intermediate between the two limits. In order to achieve maximum dissociation of NF₃ to atomic fluorine in the remote plasma source, a certain NF₃:Ar ratio and total flow must be maintained. The total flow requirements for the remote plasma source and uniform etching generally differ; the latter typically requires a substantially higher carrier flow rate. In this case, the ideal total flow and NF₃: Ar flow ratio are maintained for the remote plasma source, and the additional carrier gas is injected downstream of the remote plasma source but upstream of the cleaning gas injector. The additional carrier gas is also usually Ar. Depending on the surface area to be cleaned, multiple remote plasma sources may have to be used in tandem if the requisite NF₃ flow cannot be provided by a single source.

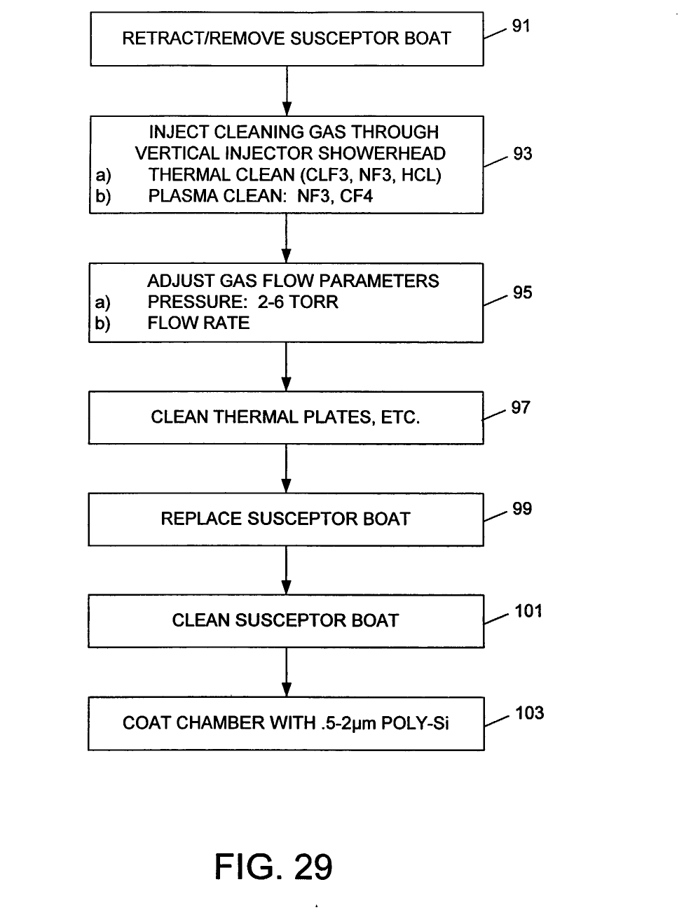

A preferred method of in-situ cleaning of a reactor according to the present invention as explained above is illustrated in the flow chart of FIG. 29. The apparatus for the novel arrangement includes a vertical gas injector showerhead for the purpose of injection of a cleaning gas, as indicated in block 93. Preferably, the susceptor boat is first removed (block 91). The cleaning gas is then injected (block 93). For a thermal clean operation, the gas may be selected from the group consisting of CIF₃, NF₃ and HCl. For a plasma clean operation, the gas may be selected from the group consisting of NF₃ and CF₄. As explained above, this pressure is preferably set in the range of 2-6 Torr, and the flow rate is then adjusted until the cleaning is uniform. This is particularly the case for the cleaning of the boat, which is the subject of block 101. Block 97 recites the cleaning of the thermal plates and other interior parts. The susceptor boat is then replaced (block 99), and the boat is cleaned (block 101). After the cleaning is completed, the interior of the chamber is coated with 0.5-2 μm of Poly-Si (block 103).

Thus the deposition process and apparatus provides for a high quality silicon layer to be deposited onto a substrate with a minimum time at elevated temperatures. The deposition time is typically 5 minutes for a 2000-angstrom layer to be deposited. Applicants have found the deposited silicon layer to have a uniformity less than 1%, as measured between the center of a wafer and a point 3 mm from the edge of both 200 mm and 300 mm wafers with surface roughness on the order of 3 to 5 nm for films 2500 angstroms thick. In addition the thermal processing involved does not warp the silicon substrates nor does it induce any crystal lattice slip in the substrate.

Achieving similar film properties on all substrates 60 also requires all substrates 60 to attain the same temperature. This can be accomplished by dividing lamps 78 (FIG. 5(a)) into multiple zones and adjusting the power in each of the lamp zones to achieve a uniform temperature along the length of the boat. For example, in FIG. 5(a), four zones 110-116 can be created by separately controlling each two rows of lamps 78 by controller 118. For illustration, FIG. 5(a) demonstrates this option by showing, for example, lamps 120 and 122 driven by a single, separate bus 124. Lamps 126 and 128 would also be driven by bus 124, as would other lamps spaced around the reactor at the same level. FIG. 5(a) only shows two sets of two lamps for zone 110 because of the planar view illustrated, but any number of lamps can be included around the reactor as space allows for uniform heating.

Each pair of susceptors 62 constitutes an isothermal back body environment. The temperature uniformity across a substrate 60 that is placed within this isothermal cavity is typically <+/−0.5° C. The power to each lamp zone is varied by controller 118 that senses the temperature of substrate 60 and adjusts the power to each zone to achieve a uniform temperature along the boat. The temperature of substrate 60 can be sensed using conventional techniques such as an array of temperature sensors 130, such as thermocouples that are placed in close proximity to substrates 60 or an array of pyrometers that image the radiation between susceptors 62. Additionally or alternatively, temperature sensors/thermocouples and/or pyrometers may be used to monitor the temperature of the thermal shields 76. The controller not only maintains a uniform temperature along the length i.e. height of the boat, but also defines the lamp power trajectory to raise the boat temperature from a standby value to its process value as quickly as possible. Each of the temperature sensors 130 are interconnected through a bus feedthrough 132 and bus 134 to controller 118. The controller 118 is programmed to adjust the power drive to the lamps in each zone to maintain the desired temperature of the boat. The temperature sensors can be a combination of thermocouples and pyrometers. Conventional methods of control such as open loop power control, PID control, multi-variate control, model based control or a combination of these techniques is employed with the objective of achieving the desired stabilized temperature uniformly along the boat and across each wafer in as short a time as possible. The mode of control may be switched during the process sequence to obtain the shortest ramp and stabilization times with good run to run repeatability of wafer temperature. For example, a PID loop optimized for fast ramp may be used during the ramp portion of the process, and a PID loop optimized for repeatable steady state control may be used during the soak and thereafter. Other methods to reduce the ramp and stabilization time include: (i) coating the inside of the wafer transfer chamber with a highly reflective coating or adding secondary heaters to minimize heat loss during wafer unloading/loading, (ii) heating the shields and the boat to higher temperatures before the boat is retracted from the chamber and while it is in transit and (iii) shortening the wafer loading/unloading times to minimize boat cool-down.

The black body isothermal environment achieves very good temperature uniformity across each substrate but the temperature of each substrate is defined by the temperature of the susceptors that envelop it. The multi-zone control described above is used to achieve a uniform susceptor temperature along the boat. However, heat loss at the top and bottom of the boat is much higher than the heat loss in the central regions of the boat. To reduce this heat loss, insulation such as 136, 138 which can be opaque quartz disks or radiation shields may be placed at the top and bottom of the boat. The insulation may be encapsulated with a material that is compatible with the deposition to minimize flaking of films that deposit on the insulation. For example, silicon carbide may be used to encapsulate the quartz disk or alternative insulating materials such as Zircar. Radiation shields can alternatively include water cooled reflective surfaces. High reflectance Rhodium or Chromium coated surfaces are commonly used to reduce radiative heat loss. As shown in FIG. 8(a), dummy susceptors 140 and 142 with insulating/reflecting disks 144, 146 substituting for substrates, may be added to the top and bottom of the boat to reduce heat loss. The inter-susceptor gap and the insulating disk to susceptor gap may be reduced for these dummy susceptors to diminish the overall increase in boat height due to these additional susceptors. Silicon carbide coated graphite liners can also be placed around the susceptor boat. These cover the cold walls and are radiatively heated by the boat thus acting as radiation shields to reduce heat loss. These liners also raise the effective wall temperature while the outer metallic chamber remains at a lower temperature. The higher liner temperature may be desirable to prevent condensation of law volatility precursors, and reaction by-products. Additionally, heating may be provided at the top and bottom of the boat to compensate for heat loss. This will be described in detail in reference to the following figures of the drawing. Also, the boat tends to cool down when it is moved to the transfer chamber for loading or unloading wafers. To minimize the temperature decay, the load/unload chamber 74 may have insulation, indicated by items 148, and/or have reflecting walls 150 and/or active heating of the boat while in the load/unload chamber.

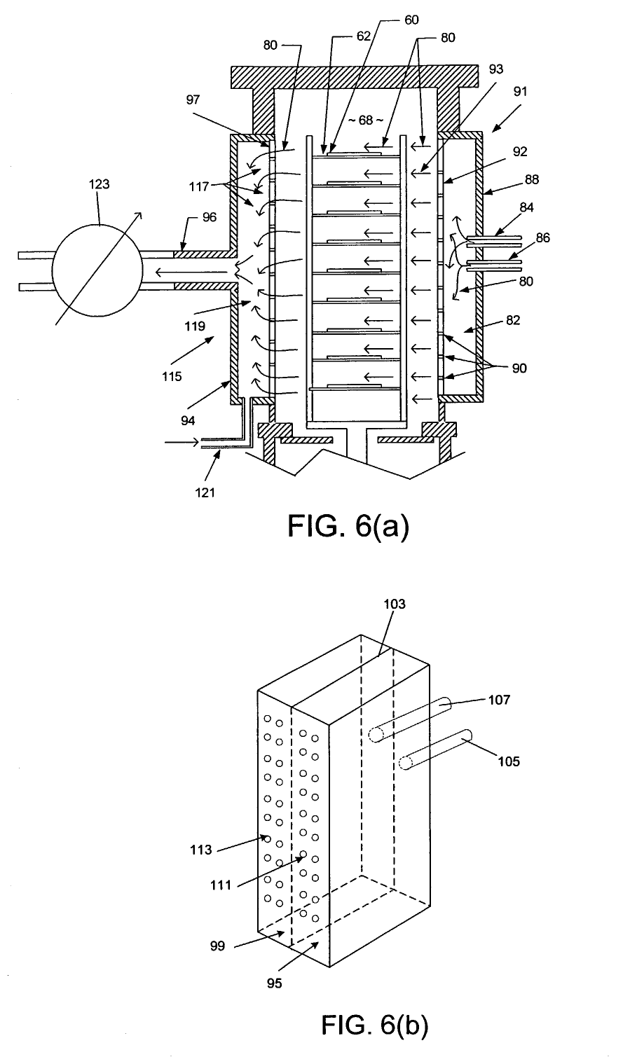

Referring to FIG. 9, a multiwafer boat 152 is shown in a reactor 154 that employs a top resistive heater 156 suspended by a support 158, and another support 160 which also serves as a feedthrough for electrical power for the heater 156. A bottom heater 162 receives power through post 164. The heaters 156 and 162 are representative, and can be of various designs known to those skilled in the art. The heaters 156 and 162 can also be used in addition to the heat insulation and reflector material discussed in reference to FIG. 8(a). Heaters 156 and 162 can also be multi zone. Details of multizone top and bottom heaters will be described in reference to the following figures of the drawing.

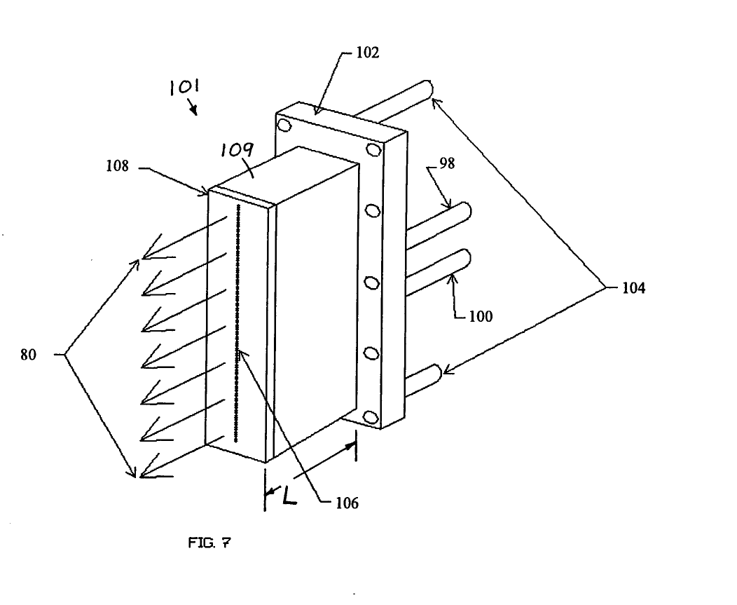

Referring now to the FIG. 10 of the drawing, a reactor 166 is shown for illustrating multizone top and bottom heaters. Reactor 166 includes a chamber housing 168 with a reactant gas input 170 and exhaust 172. A substrate carrier 174 is attached to a shaft 176 for rotating the carrier and a wafer 178. An upper multi-zone resistance heater 180 is suspended from a support structure 182 that serves to position the heater 180 relative to the wafer 178. Similarly, a lower multi-zone resistance heater 184 is positioned below the carrier 174, with support structure 186. The structures 182 and 186 also preferably extend entirely around the perimeter of heaters 180 and 184, for the purpose of preventing reactant gases from reaching the back sides 188 and 190 of the heaters 180 and 184. The reason for preventing the reactant gases from reaching the back sides of the heaters 180 and 184 is to prevent deposition of material on electrical connections and wires that are required to supply the electrical energy to resistive heater element/wires attached to or embedded in heater block material. These wires and their connections are not shown in FIG. 10. The construction of such wires and connections will be understood by those skilled in the art from reading the present disclosure. In order to further prevent reactive gases from invading the back side of the heater, an inert gas is injected into the upper space 192 and the lower space 194, behind the heaters 180 and 184, thereby preventing reactant gases from invading the upper and lower spaces 192 and 194, and preventing deposition of material on the electrical connections. The injection of inert gas is indicated by inert gas inputs 196 and 198. Alternatively, the heater structures can form a seal to atmosphere, eliminating the need for the inert purge gas.

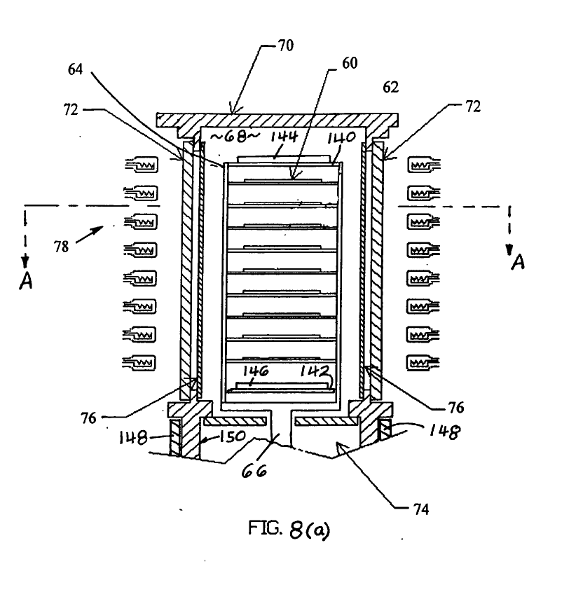

The structure of the multi-zone resistance heaters, including connections and wires for a top or bottom heater is more fully described in reference to FIG. 11, wherein a three zone heater 200 is shown having a plate 202 made of high temperature material and resistive traces 204, 206 and 208. The traces 204, 206 and 208 are attached to wires 210, 212 and 214 respectively. The wires 210, 212 and 214 are connected to independent electrical power controls such that the resistive heating traces 204, 206 and 208 are independently heated. Such an arrangement allows for applying more heating energy per square inch of heater surface to the outer traces 216 to compensate for the heat loss at the edge 218 of the heater 200. Although the heater 200 is shown with 3 zones, the present invention includes any number of heat zones, for example depending on the size of the substrate to be heated.

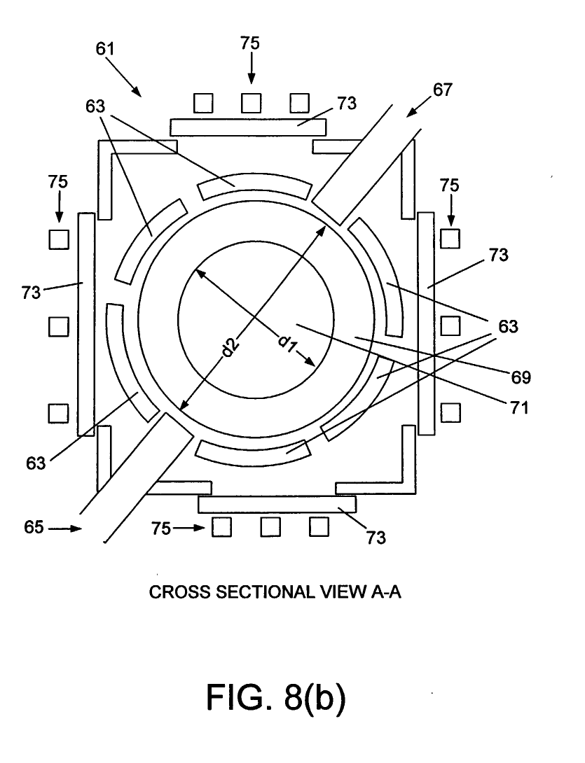

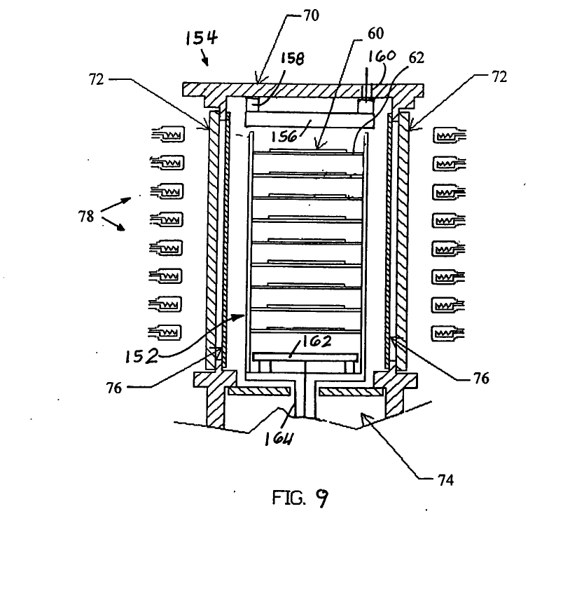

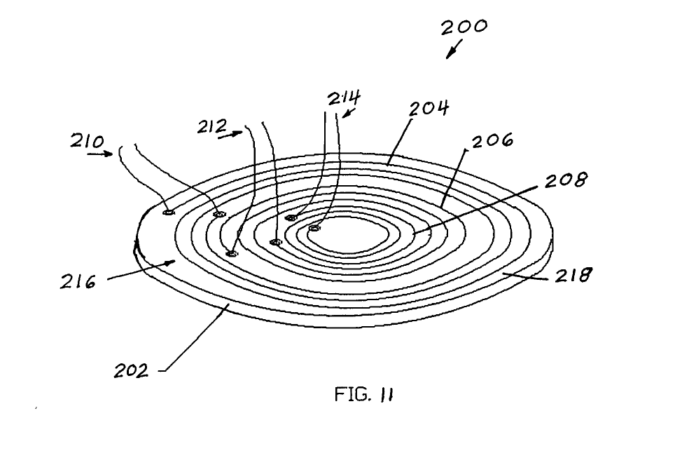

FIG. 12 is a cross-sectional view B-B referred to FIG. 13. FIG. 12 shows a reactor 220 including a CVD chamber 222 with a multi-substrate boat 224 enclosed, in which substrates 226 are supported on pins 228 attached to susceptor plates 230 which are supported on rods 232. The boat is supported by a rotating carrier 234 driven by a shaft 236 which is vacuum sealed to the chamber 222 by a rotating vacuum seal 238. The substrates 226 are heated primarily by the susceptor plates 230 which are firstly heated by a series of heaters which may include an upper heater 240 and lower heater 242 to minimize or prevent heat loss from the top and bottom ends of the stack of susceptor plates 230. Three vertically oriented side heater assemblies 244, 246 and 248 are also shown, providing three separate temperature zones. Each assembly 244, 246, 248 surrounds the boat 224 with four heaters, including one for each of the four sides of the chamber, as shown in FIG. 15. Only two heaters of each assembly 244, 246, 248 are visible in the cross-sectional view of FIG. 12. The lower heater 242 has a clearance 252 for passage of the shaft 236 for rotating the boat. As an alternate embodiment, the upper heater 240 and lower heater 242 can be eliminated by extending the length of the CVD chamber 222 and placing thermal insulation (not shown) above the upper plate 254 and below the bottom support plate 234 to minimize heat loss in these regions. The chamber can be designed with any number of zones of heaters, the choice depending on various factors such as the number of substrates that need to be processed. All the heaters are attached to the chamber walls 256 by supports such as 250, 258, and 260, configured to surround the perimeters of each heater such that the spaces such as 262, 264 are sealed to prevent reactive gases 266, shown in FIG. 13, from entering the spaces 262, 264 in which the electrical connections (not shown) are attached to the heaters. In order to further deter the reactant gases from entering the spaces 262 and 264, each space is pressurized with an inert gas. The inert gas can be injected in various ways, for example through injection ports 268.

FIG. 13 is a cross-sectional view C-C referred to FIG. 12. This view shows an injector apparatus 270 and an exhaust apparatus 272. Both the injector and exhaust apparatus include injectors and exhausts that are extended toward the boat 224 for injecting and exhausting the reaction gases parallel to each wafer 226 (FIG. 12) and at a high speed. FIG. 13 also shows vertical portions 274 and horizontal portions 276 of the supports 260 that follow the perimeter of each of the four heaters in each of the heaters 244-248 making the three zones illustrated.

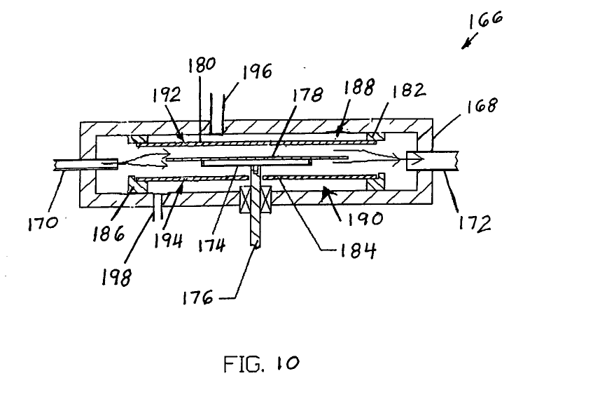

FIG. 14 is a cross-sectional view D-D, referred to FIG. 13. The reactive gases 266 enter the chamber 222 through the injector apparatus 270 including gas injectors 278 and flow across the substrates 226, and exit the chamber 222 by exhaust apparatus 272 ports 280 which in operation are attached to a vacuum pump (not shown). Such an arrangement allows for a high velocity gas flow resulting in an enhanced rate of deposition of material onto the substrates 226.

FIG. 15 is a perspective view showing the arrangement of heater assemblies 244, 246 and 248 for separately controlling the temperature of three zones. Heater assembly 244, with four heaters 282-288 provide the upper heat zone. Electrical leads 290, 292, 294 and 296 are connected to a common power supply (not shown). The heater assembly 246 provides the center heat zone and in like manner includes four heaters 298, 300, etc., with electrical leads 302, 304, etc. also connected to a common power supply that is preferably independently controllable for supplying power to the upper heat zone. Heater assembly 248 provides the lower heat zone, and includes four heaters 306, 308, etc., with electrical leads 310, 312, etc., connected to a separately controllable power source. Such an arrangement of multi-zones of heater control allows for variations of heat over the length of the CVD chamber as the required heat varies from the upper most substrate to the substrate at the lowest position. The heating arrangement shown in FIG. 15 depicts three zones of heaters with each zone having four heaters of equal size. Obviously, the number of heat zones can be any convenient number as required and each zone can include any number of heaters, and the heaters need not be the same size.

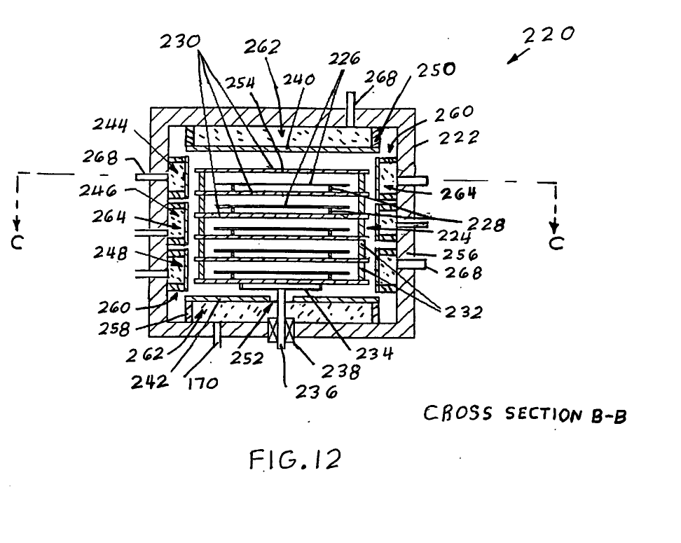

FIG. 16 illustrates integrating multi-zone heaters into the walls of a vacuum chamber. Vertical wall 314 has three independent heaters 316, 318 and 320 arranged to control the temperature along a vertical stack of substrates such as that shown in FIGS. 12 and 13. Identical heaters are preferably placed in each of the four walls shown, or alternatively, the heater coils for each heater can continue around the entire chamber. As an alternate embodiment, the top wall 322 is shown to have for example, two heaters 324 and 326 for varying the temperature along the radius of the wafer surfaces. The bottom wall, not shown, preferably has a heater similar to that integrated into the top wall 322. The bottom wall, not shown, preferably includes a removable portion for entrance and exit of a wafer boat. Gas injector 328 and exhaust 330 are symbolically shown, and can include any of a variety of injector apparatus for optimum injection and exhaust across each wafer in the wafer stack. The construction details of access to the chamber, and the injectors will be understood by those skilled in the art upon reading the contents of the referenced prior applications of which the present application is a continuation-in-part.

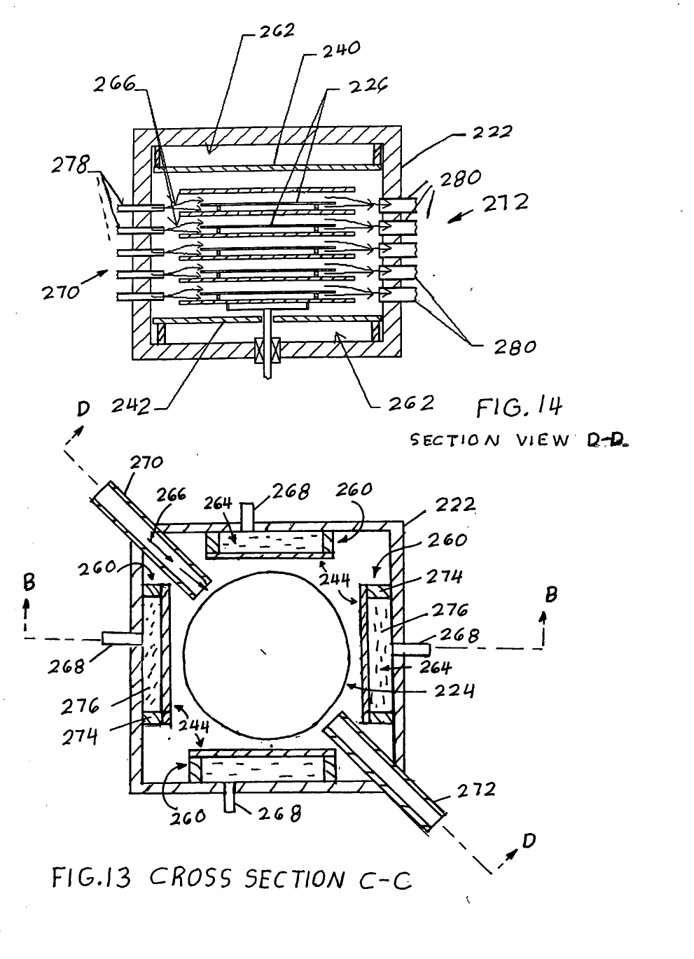

A further embodiment of the present invention will now be described in reference to FIG. 17 of the drawing. FIG. 17 is a cross sectional view showing the relevant elements of a chemical vapor deposition (CVD) reactor. Details of reactor design are fully explained in U.S. patent application Ser. Nos. 08/909,461 filed Aug. 11, 1997; 09/229,975 filed Jan. 14, 1999; 09/228,840 filed Jan. 12, 1999; 09/396,588 filed Sep. 16, 1998; 09/396,586 filed Sep. 16, 1998, and 09/396,590 filed Sep. 16, 1998, and the entire contents of these applications are incorporated in the present disclosure by reference.

FIG. 17 shows elements of a boat 332 including a stack of plates 334-342. Plate 334 serves as an upper plate above a lower plate 336. In addition to serving as a lower plate, plate 336 functions as an upper plate relative to plate 338, and so on for the remainder of the stack, with plate 342 functioning only as a lower plate. Apparatus for suspending substrates 344-350 between the plates is provided. FIG. 17 illustrates a preferred embodiment of a suspension apparatus including pins 352 extending upward from each of plates 336-342, each serving as a lower plate to a corresponding space in which a substrate is suspended. The plates 334-342 are supported by apparatus as described in the parent applications noted above and incorporated herein by reference. Pins of varying heights can be included so that multiple wafer sizes can be placed on any given susceptor. Additional pins may be included to capture the wafer in case it slides off the primary pins making for a more fault-tolerant design. Other apparatus for suspending a substrate between two plates will be apparent to those skilled in the art, and these variations are to be included in the spirit of the present invention.

The stack requires at least two plates, but can be any larger number for processing a corresponding number of substrates. The boat 332 is preferably mounted on a rotatable pedestal 354. An important feature of the present invention includes a thermal side plate or plates, such as 356 and 358 positioned preferably close to the boat 332 and preferably oriented orthogonal to the susceptor plates 334-342 as shown. Other configurations and orientations of material for serving the function of the thermal side plates are also included in the spirit of the present invention. The boat 332 and thermal plates 356 and 358 are all inside a reactor housing, the details of which are fully described in the parent applications incorporated by reference. The thermal side plates or shields 356 and 358 serve three purposes. First, they prevent unwanted deposition on the quartz windows although this not a concern for certain applications such as oxidation, annealing or surface treatment. Second, they smear the effect of the individual tungsten halogen lamps or infrared heating elements 364 for more uniform heating of the boat 332. Third, they can be used to reduce the flow of reactant gases around the boat. However for certain applications such as oxidation, annealing and surface treatment, the thermal shields may be absent and the boat can be heated directly by the lamps. The thermal shields may be fabricated in multiple sections for ease of manufacture and also to minimize chances of cracking during operation. If the shield is too large, thermal stresses induced during temperature ramping or cool-down can crack the thermal shields. Segmentation may be performed along lines of symmetry to cause minimum disruption to the temperature and gas flow uniformity. The joints between adjacent segments have to be designed to provide good thermal contact and a good seal for the purge gases that flow between the thermal shields and the quartz windows. The reactor housing includes windows 360 and 362, or as illustrated in FIG. 5(a) as items 76 which are preferably constructed of quartz, for passage of heat energy. The heaters 364 are preferably halogen lamps, and are positioned outside the reactor housing. In operation, the heaters radiate heat energy through the quartz windows 360 and 362 and heat the thermal plates 356 and 358. The heated plates 356, 358 then radiate heat energy, heating the plates 334-342. The heated thermal mass of the side plates 356, 358 and plates 334-342 provide a uniformly heated environment/heat source for heating the suspended substrates 344-350. Suspending each substrate 344-350 between first and second plates avoids any undue influence by one of the plates, and results in a more uniform substrate temperature than what is achievable using the common procedure of laying a substrate directly onto a susceptor plate.

Although quartz windows 360, 362 and exterior heaters 364 are shown in FIG. 17, other methods for heating plates 356 and 358 will be understood by those skilled in the art and these are to be included in the spirit of the present invention. Furthermore, the heating plates 356 and 358 could be replaced with solid heater plates, which contain resistive heating elements wherein the resistively heated heater plates themselves would form the required vacuum seal. Thus, the quartz windows and external lamp heaters would not be required.

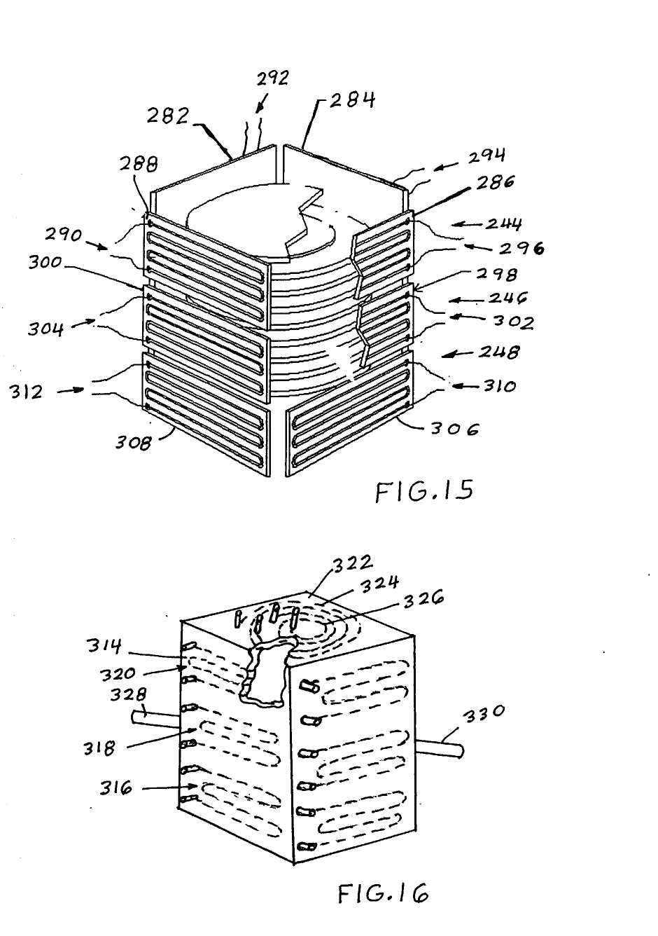

In further description of the method and apparatus of FIG. 17, once the thermal side plates 356, 358 and plates 334-342 are heated to equilibrium by the heaters 364, the upper surface 366 for example of substrate 344 is heated by the lower surface 368 of plate 334, and the lower surface 370 of substrate 344 is heated by the upper surface 372 of plate/susceptor 346. It should be noted that the term “susceptor” is commonly used to describe a plate for holding a substrate, and therefore plates 336-342 can be properly called “susceptors” as well as by the more descriptive terms of upper and lower thermal plates. The method and apparatus of the present invention described above, improves the temperature uniformity across the substrates 344-350 as compared to the prior art method of placing a substrate such as 344 directly on the surface of a susceptor such as 336. The method of suspending a substrate according to the present invention preferably places each substrate in a substantially centered position between two plates, with the suspending apparatus allowing relatively free gas flow on both sides of the substrate, i.e., both above and below the substrate. An example of a method of suspending a substrate above a susceptor surface that is not preferred is illustrated for example in FIG. 18, wherein a substrate 374 is suspended above a surface 376 which is the bottom of a recess 378 in a susceptor 380. The configuration of FIG. 18 does not allow free gas movement in the space 382 below the substrate 374, and as a result the temperature of substrate 374 is unduly influenced by the temperature of the susceptor 380 as compared to the influence of the plate/susceptor 384 positioned above the substrate 374. The preferred embodiment of the present invention therefore includes an apparatus for suspending a substrate between two plates while allowing substantially equal gas flow both above and below the substrate. A further aspect of the preferred suspending apparatus is that it allows access to the space below each substrate for a tool for lifting the substrate for placement and removal of the substrate to and from the boat 332. In general, the position of the substrate in the gap between adjacent susceptors depends on the above mentioned criteria as well as the need to control the uniformity of film properties on the front and backside of the substrate. Typically, the requirement for uniformity of film properties is more stringent for the front of the substrate relative to the back of the substrate and thus the substrate may be positioned so that the gap between the substrate and the susceptor is unequal on either side of the substrate. The gap between the front side of the substrate and the adjacent susceptor is preferably greater than the gap between the backside of the wafer and the corresponding adjacent susceptor. By adjusting the susceptor temperatures to be equal, the substrate temperature equilibrates to the susceptor position irrespective of the position of the substrate within the gap between adjacent susceptors. Placing the substrate above the plane of the susceptor also cools the wafer edge slightly which compensates for the slightly higher deposition rate at the wafer edge due to a slightly higher concentration of reactant at the wafer edge. Thus deposition uniformity is slightly improved over the case when the substrate lies in the plane of the susceptor.

Referring again to the operational performance, the actual temperature uniformity across a substrate during operation is difficult to measure and is inferred by measuring the uniformity of deposition across the substrate and from one substrate to another substrate. For example, the uniformity of polycrystalline silicon deposited on a substrate such as 344 when placed on pins 352 and heated between plates 334 and 336 as shown in FIG. 17 is typically 0.25 percent, 1 sigma, implying a temperature variation of less than 0.25 degrees C. across the substrate. In comparison, the typical uniformity of polycrystalline silicon across a 200 mm diameter substrate when the substrate is placed in contact with a susceptor such as depicted in FIG. 18 is 0.5 percent. An additional advantage of the apparatus of FIG. 17 is that the deposition is approximately equal on both surfaces/sides of the substrates 344-350 as a result of suspending the substrates on pins 352. In comparison, the deposition uniformity on the lower surface of the substrate 374 of FIG. 18 is much worse than on the upper surface of the substrate. As mentioned above, an additional advantage of placing the substrate(s) 344-350 on the raised pins 352 is that a robot arm (not shown) can place and remove the substrate(s) 344-352 from the boat 332 in a CVD chamber without having to incorporate a separate mechanism to lift the substrates off the susceptor. It is also desirable to minimize contact with the backside of the substrate to reduce particles on the backside of the substrate as well as particle generation when the substrate is removed following the deposition. Substrate 374 of FIG. 18 contacts the susceptor along its circumference which is undesirable for the aforementioned reason.

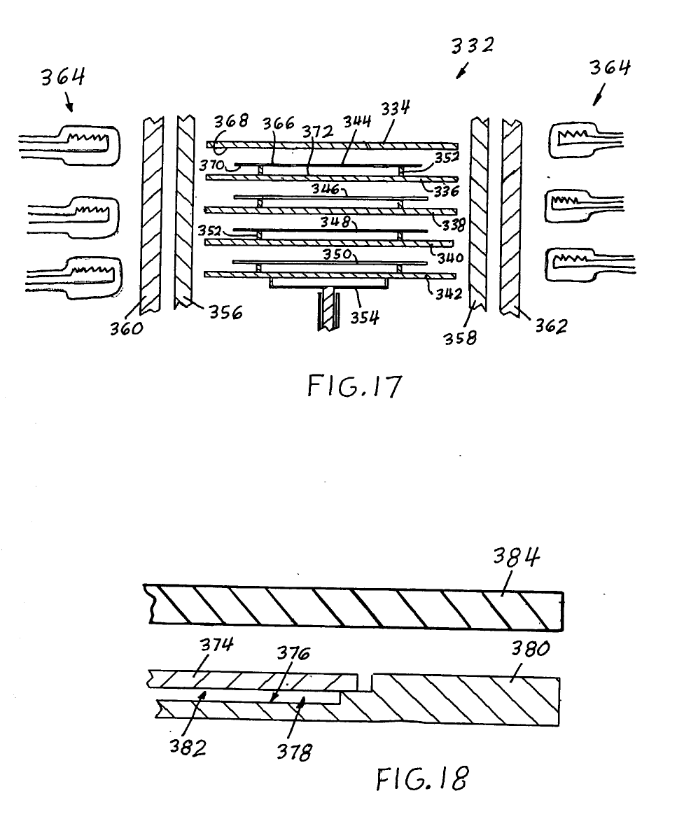

FIG. 19 illustrates the use of a first set of pins 386 for suspending a first wafer 388 having a first diameter 390. Only two pins 386 are shown in FIG. 19 for ease of illustration. The set of pins 386 preferably includes at least three, arranged substantially on a circumference at a circle in order to properly support a circular substrate in suspension above the plate/susceptor 392. It will be understood by those skilled in the art that in the apparatus shown in FIG. 17, at least three pins per substrate are also preferred for adequate support, whereas only two are shown in order to simplify the descriptive figure. For larger substrate diameters, such as 300 mm substrates, additional points of support may be provided at different radii on the susceptor since the larger diameter substrates tend to sag at elevated temperatures.

FIG. 19 also shows a second set of pins 394 that are also preferably at least three in number, and arranged on a circumference of a circle. The diameter D2 is less than D1 and therefore the inclusion of pins 394 allows for accommodating a substrate 396 of smaller diameter than D1 without the need to change or modify the boat. The height H2 of the pins 394 is less than the height H1 at which the larger diameter substrate 388 would reside if in place.

FIG. 19 also illustrates the use of a recess 398 in each of the pins 386 and 394. The purpose of the recess 398 is to provide lateral capture/restriction of the substrate 388, 396. This restriction/capture is desirable in order to keep the substrate 388, 396 in place during the deposition procedure which preferably includes rotating the boat 332.

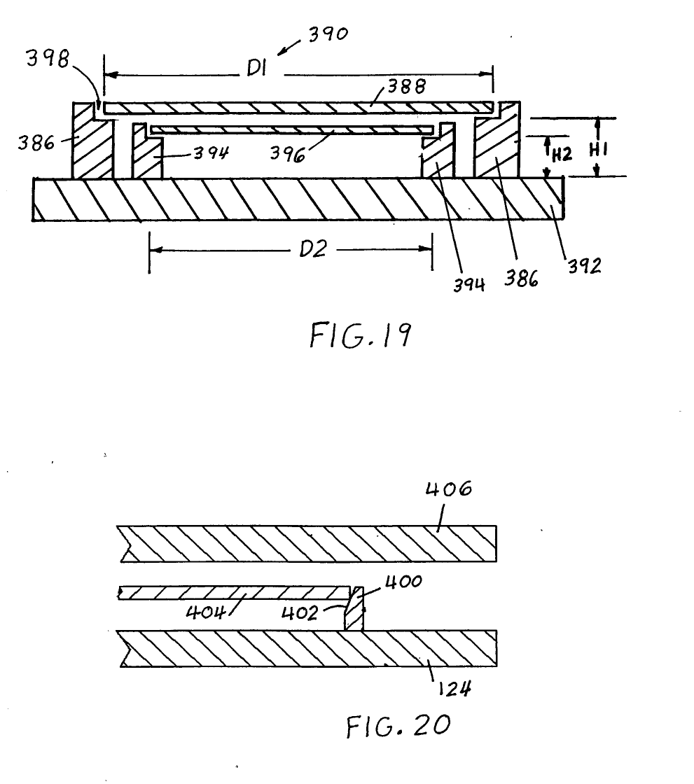

FIG. 20 shows an alternate apparatus for lateral substrate containment wherein each of a plurality of pins 400 (only one shown), have a beveled edge 402 for capturing a substrate 404 and suspending the substrate 404 between the plates 406, 408. The beveled edges 402 have the advantage of reducing the contact area to the substrate and therefore reducing thermal conduction from the pins to the substrate. Such an arrangement helps prevent crystal slip induced defects of the substrate 404 during high temperature processing, i.e. typically 900° C. or above.

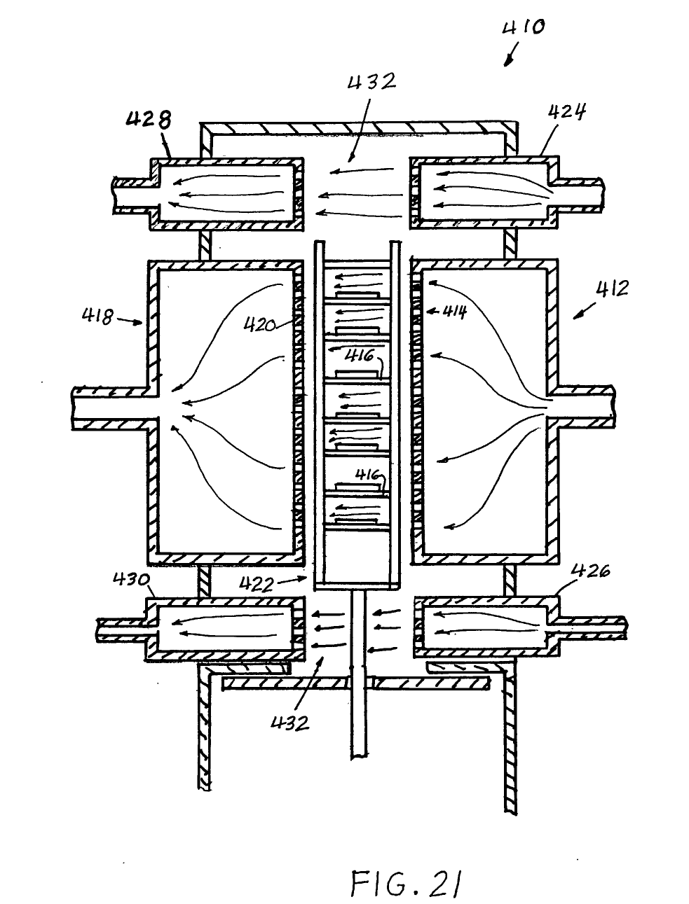

The principle described above referring to injecting inert gas to avoid unwanted deposition is illustrated in the reactor 410 of FIG. 21. The view of FIG. 21 is a cross section along the line of the injectors, similar to section D-D indicated in FIG. 13. A reactant gas injector 412 has an injector plate 414 positioned close to the susceptors 416 so as to concentrate the reactant gas between each susceptor pair. The reactant gas exhaust 418 is also configured with an exhaust plate 420 positioned close to the susceptor opposite the injector plate 414. The intent of the positioning and configuration of the injector 412 and exhaust 418 includes confining the reactant gas as much as possible to the area between the susceptors in order to avoid unwanted deposition elsewhere in the reactor 410. Because some of the reactant gas will migrate above and below the boat 422, inert gas injectors 424 and 426 are positioned above and below the boat 422 with corresponding inert gas exhausts 428 and 430. The inert gases 432 sweep out and replace reactant gases above and below the boat 422, thereby minimizing deposition in those areas.

The injector 412 and exhaust 418 shown are given by way of illustration of a preferred embodiment. Other designs for accomplishing the purposes set forth above will be apparent to those skilled in the art, and these are to be included in the spirit of the present invention.

Although many features of the present invention have been set forth separately, the present invention also includes combinations of the features. For example, FIG. 21 illustrates the inert gas injection, and FIGS. 10-16 illustrate multizone heating. The present invention also includes the combination of multizone heating with inert gas injectors as set forth in reference to FIG. 21. Similarly, the concentrated, rapid reactant gas flow set forth in reference to FIGS. 4-7, and the insulation-reflection principle of FIGS. 8(a-b) and 9 are all combinable in one reactor for optimum performance. The various principles are each novel, but are also advantageously combinable in one reactor, and are illustrated separately for ease of description and to clearly point out the various novel concepts of the present invention.

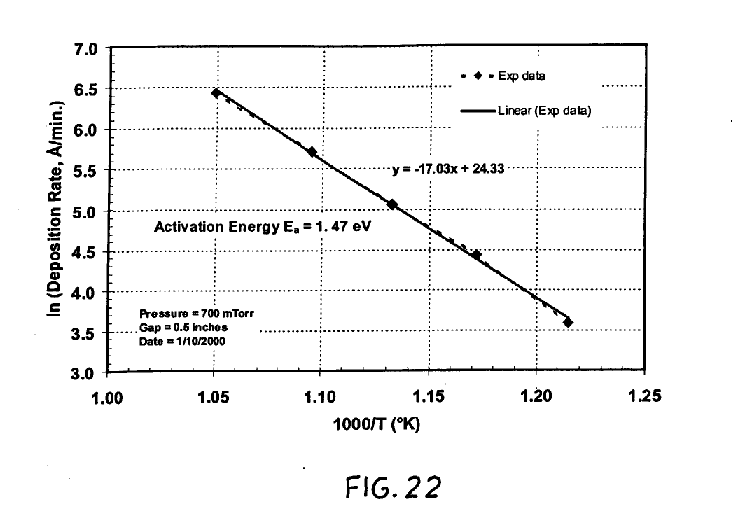

FIGS. 22-26 exemplify performance aspects of the multi-batch reactor configured and operational according to the present invention as described in reference to FIGS. 4-7 incorporating the method of FIG. 4. FIG. 22 is a plot of the deposition rate as a function of the inverse absolute temperature. The vertical axis values are the natural logarithms of the deposition rate. FIG. 22 is an Arrhenius plot and shows that the reaction remains in the surface rate limited regime over a wide temperature range with no evidence of gas depletion effects. If there were gas depletion, the plot would not be a straight line. In a conventional furnace that does not have “across the wafer” gas flow, the Arrhenius plot would be a straight line at lower temperatures and a roll-off would be observed at higher temperatures.

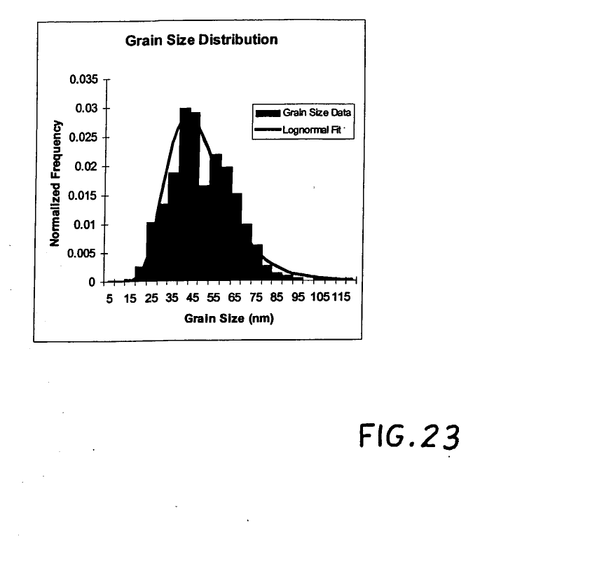

FIG. 23 is a bar chart of frequency versus grain size. The chart is a histogram showing the relative distribution for various grain sizes. In any film, the grain size is not constant, but has a distribution. The histogram represents this distribution. The plot shows that the median grain size of 50 nm is 30% of film thickness (150 nm film). Also the distribution is well represented by a log normal distribution. Polysilicon films deposited in conventional furnaces show a similar grain size distribution in terms of the shape of the curve, but the median grain size is typically 50% of film thickness.

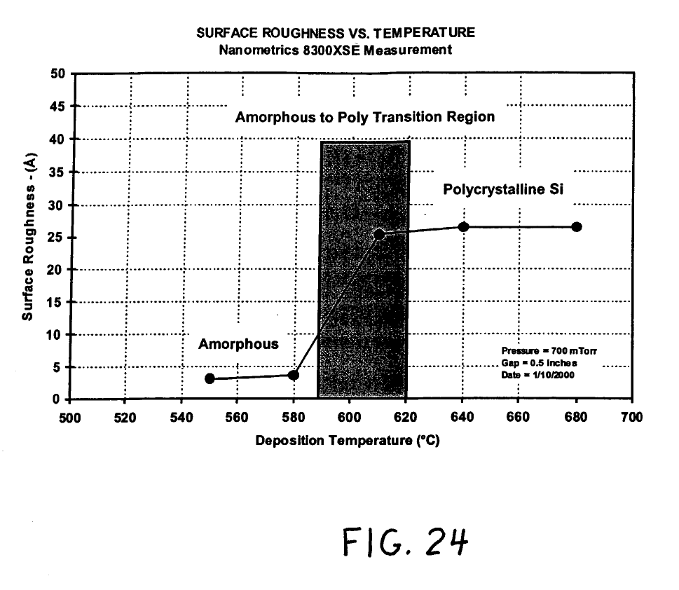

FIG. 24 is a plot of surface roughness as a function of temperature, while maintaining >10 cm/sec reactant gas velocity, a pressure of 700 mTorr, and a susceptor to susceptor gap of 0.5 inches. The plot of FIG. 24 shows that film-surface roughness remains low even as the deposition temperature is varied over an extended range because of the absence of gas depletion and minimal gas phase SiH₂ formation for the short residence times employed.

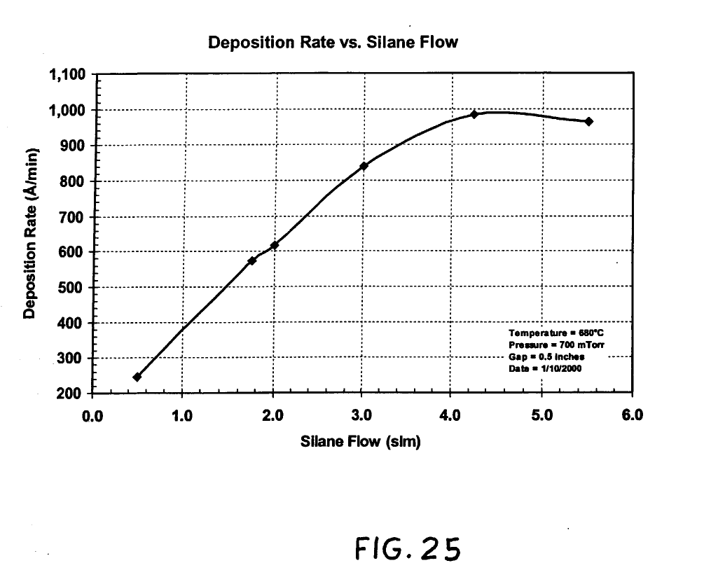

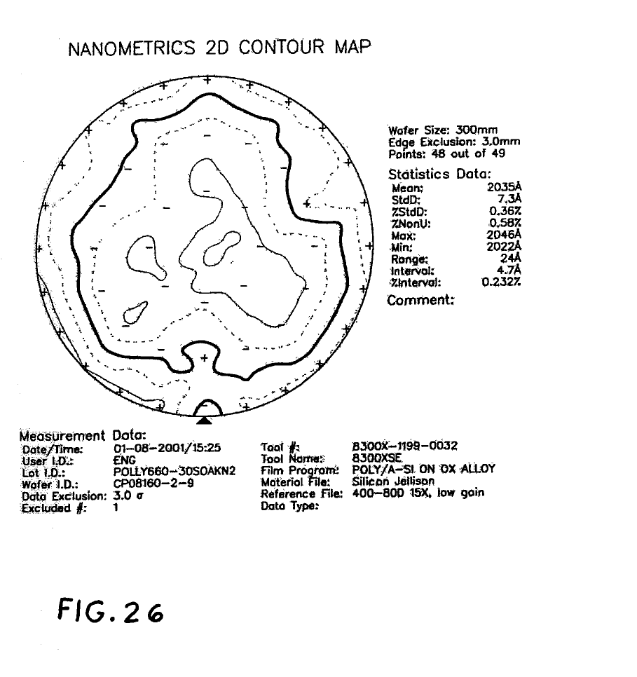

FIG. 25 is a plot of the deposition rate as a function of the volumetric rate of silane flow, showing the rapid rise in deposition rate when the flow is increased with the confined 0.5 inch gap and the low pressure of 700 mTorr. For polysilicon, the deposition rate increases linearly initially with an increase in the volume of SiH₄ flow as the partial pressure of SiH₄ above the wafer increases, but at sufficiently high SiH₄ partial pressures when all surface sites on the wafer are saturated with the reactant, the deposition rate levels off. In general, higher volumetric SiH₄ flow rates are undesirable because high SiH₄ partial increases the likelihood of gas phase reaction and the cost associated with higher consumption of SiH₄. The present invention provides a high rate of reactant flow at the wafer surface i.e. across the wafer due to the increased velocity, and therefore at moderate volume flow rates. The “across the wafer” gas flow insures that uniform film properties are achieved across the wafer even at low volume flow rates of SiH₄ when the deposition rate is dependent on SiH₄ flow. FIG. 26 is a contour map of the results of making 49 measurements of the poly film thickness in a concentric circular pattern across the diameter of the wafer. This shows the enhanced uniformity of a polysilicon film deposited via the present invention. A key concept of the present invention is a controllable high rate of gas flow across the wafer. The high rates of deposition achieved are a consequence of the higher gas flow rates across the wafer. The higher flow rate across the wafer allows the reactor to operate at higher pressures than prior art reactors while achieving good film properties and a high rate of deposition. Control of gas supply to the wafer and gas residence time over the wafer is possible only with cross wafer gas flow. The high cross wafer gas velocities mentioned are specific to poly-Si. Different values would apply to other processes as mentioned earlier.

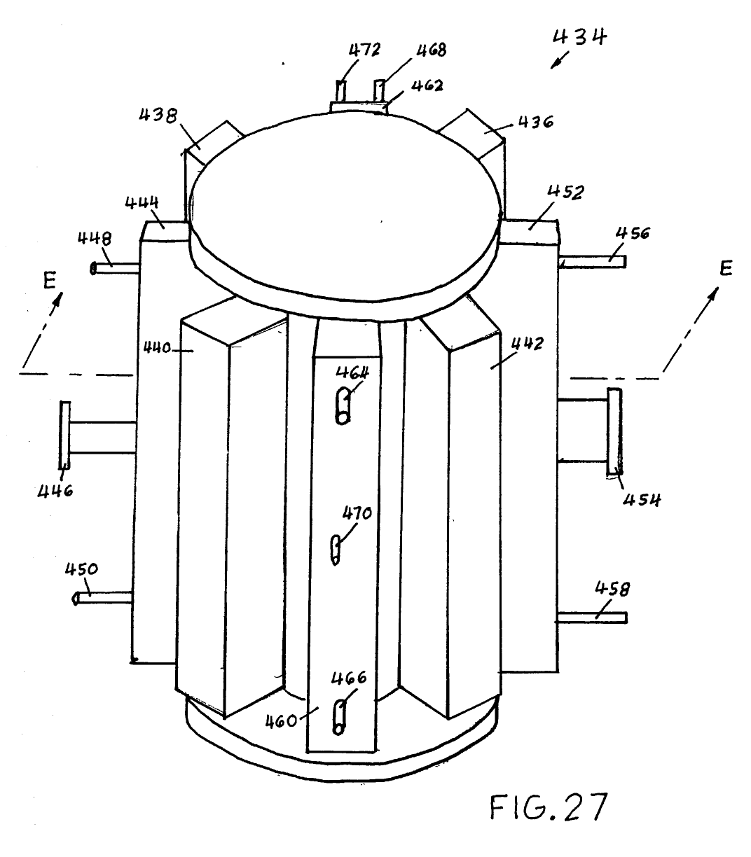

Referring now to FIG. 27, a perspective exterior view of a reactor 434 is illustrated for the purpose of showing alternating heating and temperature controlled zones. There are four heater assemblies 436, 438, 440 and 442, defining four heating zones. The areas between the heaters are called temperature controlled zones. Within these controlled zones are located other apparatus required for operation of the reactor. A reactant gas injector assembly 444 is shown with a gas input port 446. A liquid coolant inlet 448 and exit 450 provide for flow of a coolant through coolant passages (not shown) in the injector 444 housing in order to control the temperature of the injector 444 which needs to be kept relatively low in order to avoid deposition of reactants on the injector 444 surfaces. Similarly, a reactant gas exhaust 452 assembly is shown with a reactant gas exhaust port 454, and a coolant inlet 456 and outlet 458. Two additional assemblies 460 and 462 are shown, with coolant ports 464, 466, 468, and another port not shown for assembly 462. The assemblies 460 and/or 462 can be constructed for any of a variety of purposes. For example, a port 470 can be used to inject a plasma, or other matter for an in-situ cleaning procedure. Another example would be a port 472 for passing electrical lines, or other types of lines into the reactor for any of various reasons, such as temperature monitoring.

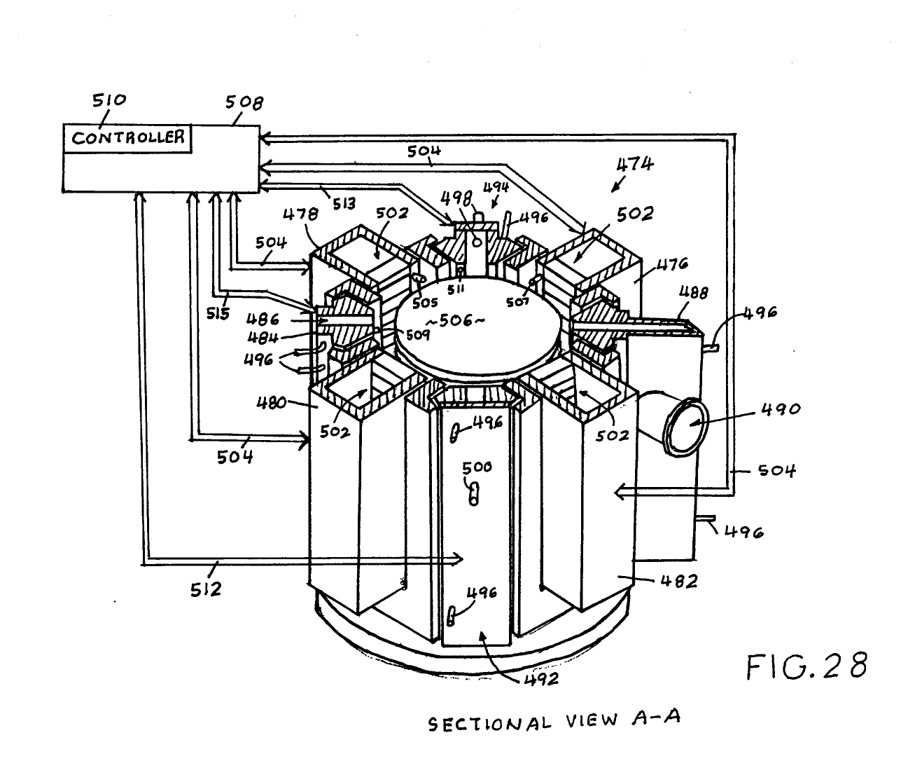

FIG. 28 is a cross sectional view E-E in reference to FIG. 27, and shows further detail of a preferred embodiment of the construction of a reactor similar to that shown in FIG. 27. As in FIG. 27, there are four heater assemblies, 476, 478, 480 and 482. As an alternate embodiment to the electrical heaters shown in FIG. 28, each heater assembly can be a series of heat lamps positioned exterior to the chamber, with a heat transmitting window forming a portion of the chamber wall for transmission of radiated heat from the lamps to a thermal heat plate positioned inside the chamber for transmitting heat to the susceptors. This configuration of heating is similar to that illustrated in FIG. 5(a). A reactant gas injector assembly 484 is shown with an elongated rectangular gas feed port 486. A reactant gas exhaust 488 has an exhaust port 490. Assemblies 492 and 494 provide access for any of various purposes as discussed in reference to FIG. 27 and corresponding assemblies 460 and 462. Coolant lines 496 are indicated (two per assembly preferred), which are used to supply a liquid to cooling channels (not shown) in each of the assemblies 484, 488, 492 and 494. Ports 498 and 500 symbolize access for any of various purposes such as an in-situ cleaning gas, a plasma, or access for monitoring, etc. For in-situ cleaning, assembly 494 can be a vertical shower head injector for injecting a cleaning gas. The injector, for example, can be of the type illustrated in FIG. 7. The cooled assemblies 484, 488, 492 and 494 define four temperature controlled/cooled zones between the heaters (heating zones). The cooler, temperature controlled zones are an improvement over the prior art because the cooler temperatures resist deposition of reactant gases on the interior surfaces of the assemblies 484, 488, 492 and 494, and therefore minimize the frequency of required cleaning procedures to remove the unwanted deposits, which otherwise eventually flake off and contaminate the desired deposition on the wafers.

The heater assemblies 476-482 each have a plurality of independently controllable heaters 502, empowered by current supplied through cables such as 504. The temperature over the length of the boat 506 is held more uniform by adjusting/controlling each of the plurality of heaters 502. As an alternate embodiment, a plurality of temperature sensors, indicated symbolically as item 505 and 507, can be distributed over the height of the reactor 474 to provide for temperature monitoring, and can be connected to a power supply apparatus 508, including a controller 510. FIG. 28 shows power cables 504 connected to the supply 508, and a cable 512 carrying connection/wires from the temperature sensors. As an alternate embodiment, temperature sensors 509 and 511 are shown to illustrate sensors attached to structure in the cooled temperature controlled zones. Sensors of any quantity can be placed in either the heated zones or the cooled zones. Lines 513 and 515 illustrate electrical lines for connecting sensors in the temperature cooled zones to the controller apparatus 510 which can alternatively contain additional control functions for controlling any apparatus for controlling the temperature of the cooled zones. The temperature controller 510 can for example control the temperature of supplied coolant, or a heater. In most embodiments shown here, four heater banks are shown, but a smaller or larger number of banks can be used depending on the size of the chamber.

While particular embodiments of the present invention have been shown and described, it will be obvious to those skilled in the art that changes and modifications may be made without departing from this invention, and therefore, the appended claims are to encompass within the scope all such changes and modifications as follow within the true spirit and scope of this invention.

What is claimed is:

1. A reactor for deposition of a material onto a plurality of substrates in a deposition chamber comprising:
(a) a boat having a vertical stack of horizontally oriented susceptors for holding substrates, wherein a spacing between susceptors is in the range of 0.2 to 1.5 inches;
(b) a reactant gas injector configured with a plurality of reactant gas injection openings for directing a concentrated flow of reactant gas across each said substrate on each said susceptor; and
(c) a reactant gas exhaust configured with an exhaust entrance positioned opposite each said susceptor from said injection plate for drawing said reactant gas across each said susceptor.

2. A reactor as recited in claim 1 wherein said injection openings are positioned from a said susceptor a distance less than said spacing between said susceptors.

3. A reactor as recited in claim 1 wherein a ratio of a distance between said openings and said susceptors to said spacing between said susceptors is in the range of 0.33 to 1.0.

4. A reactor as recited in claim 3 wherein a ratio of a distance between said openings and said susceptors to said spacing between said susceptors is in the range of 0.33 to 1.0.

5. A reactor as recited in claim 1 further comprising thermal plate apparatus inside said chamber and extending at least a height of said boat and having a minimum spacing from said susceptors in the range of 0.05-1.0 inches.

6. A reactor as recited in claim 5 wherein said thermal plate apparatus extends substantially around said boat, leaving space therethru for said injector apparatus and said exhaust apparatus to extend toward said susceptors.

7. A reactor as recited in claim 1 further comprising multi-zone heater apparatus for heating said boat providing a plurality of independently controllable zones of heating.

8. A reactor as recited in claim 7 wherein said multi-zone heater apparatus provides a plurality of said zones over a height of said boat.

9. A reactor as recited in claim 7 wherein said multi-zone heater apparatus provides a plurality of said zones above said boat.

10. A reactor as recited in claim 9 wherein said multi-zone heater apparatus provides a plurality of said zones below said boat.

11. A reactor as recited in claim 1 further comprising
(a) inert gas injector apparatus for injecting an inert gas above said boat; and
(b) inert gas exhaust apparatus including apparatus positioned above said boat for exhausting said inert gas.

12. A reactor as recited in claim 11 wherein
(a) said inert gas injector apparatus is further for injecting an inert gas below said boat; and
(b) said inert gas exhaust apparatus includes apparatus positioned below said boat for exhausting said inert gas.

13. A reactor as recited in claim 1 further comprising:
(a) at least one thermal side plate for radiating heat energy to heat said susceptors; and
(b) apparatus for suspending a substrate between an upper said susceptor and a lower said susceptor.

14. An apparatus as recited in claim 13 wherein said side plate is oriented substantially orthogonal to an orientation of each of said upper and lower susceptors.

15. An apparatus as recited in claim 13 further comprising lateral containment apparatus for restraining a substrate from substantial lateral movement.

16. An apparatus as recited in claim 13 wherein said apparatus for suspending is configured to provide substantially free flow of reactant gases both above and below said substrate.

17. A reactor as recited in claim 1 further comprising:
(a) a first plurality of heater assemblies spaced around said boat; and
(b) a second plurality of temperature controlled assemblies wherein a said temperature controlled assembly is positioned on each side of each said heater assembly.

18. A reactor as recited in claim 17 wherein said temperature controlled assemblies include a reactant gas injector.

19. A reactor as recited in claim 17 wherein said temperature controlled assemblies include an exhaust apparatus.

20. A reactor as recited in claim 17 wherein said temperature controlled assemblies include a remote plasma injector for performing an in-situ cleaning of said reactor.

21. A method for depositing material on a plurality of substrates in a deposition chamber comprising:
(a) positioning said substrates on a boat in a vertical stack of horizontally oriented substrates between susceptors having a spacing between a pair of susceptors in the range of 0.2-1.5 inches;
(b) injecting a reactant gas across each said substrate in a concentrated flow with an injector apparatus at a speed in excess of 10 cm/sec; and
(c) exhausting said reactant gas with an exhaust apparatus positioned opposite each said substrate from said injector apparatus.

22. A method as recited in claim 21 wherein said injector includes injector openings positioned from a said susceptor a distance less than said spacing between a pair of said susceptors.

23. A method as recited in claim 21 further comprising heating said wafers with a heated thermal plate apparatus inside said chamber, wherein said plate apparatus is spaced from said susceptors an amount in the range of 0.05-1.0 inches.

24. A method as recited in claim 23 wherein said thermal plate apparatus extends substantially around said boat, leaving space therethru for said injector apparatus to be positioned to perform said injecting and said exhaust apparatus to be positioned to perform said exhausting.

25. A method as recited in claim 21 further comprising separately heating a plurality of zones of said boat.

26. A method as recited in claim 21 wherein said zones include a plurality of zones over a height of said boat.

27. A method as recited in claim 21 wherein said zones include a plurality of zones above said boat.

28. A method as recited in claim 27 wherein said zones include a plurality of zones below said boat.

29. A method as recited in claim 21 further comprising
(a) injecting inert gas above said boat; and
(b) exhausting said inert gas with an exhaust positioned above said boat.

30. A method as recited in claim 29 further comprising
(a) injecting inert gas below said boat; and
(b) exhausting said inert gas with an exhaust apparatus positioned below said boat.

31. A method as recited in claim 21 comprising:
(a) suspending at least one substrate of a first diameter between an upper said susceptor and a lower said susceptor; and
(b) heating said upper and lower susceptors by applying heat to a thermal plate apparatus;
whereby said upper and lower susceptors radiate heat energy to heat each said substrate.

32. A method as recited in claim 21 wherein a substrate diameter is less than a susceptor diameter for providing a thermal boundary layer wherein a reactant gas is pre-heated by said susceptor prior to reaching a said substrate.

33. A method as recited in claim 32 wherein a length of said boundary layer is in the range of two to five times said spacing between a pair of susceptors.

34. A method as recited in claim 21 wherein said injecting and exhausting are further controlled to cause a gas pressure in said chamber of less than 3 Torr.

35. A method as recited in claim 34 wherein said gas pressure is less than 1 Torr.

36. A method as recited in claim 34 wherein said gas pressure is in the range of 100 to 2000 mTorr.

37. A method as recited in claim 31 wherein said suspending provides for substantially free flow of reactant gases both above and below said substrate.
